(19) United States
(12) Patent Application Publication
(10) Pub. No.: US 2026/0068184 A1
(43) Pub. Date: Mar. 5, 2026

(54) MEMORY DEVICE COMPRISING MULTIPLE CHIPS WITH CAPACITOR IN PROCESSOR IN MEMORY PORTION

(71) Applicant: QUALCOMM Incorporated, San Diego, CA (US)

(72) Inventors: Jihong CHOI, San Diego, CA (US); Mustafa BADAROGLU, San Diego, CA (US); Woo Tag KANG, San Diego, CA (US); Giridhar NALLAPATI, San Diego, CA (US); Zhongze WANG, San Diego, CA (US); Periannan CHIDAMBARAM, San Diego, CA (US)

(21) Appl. No.: 19/313,646

(22) Filed: Aug. 28, 2025

Related U.S. Application Data
(60) Provisional application No. 63/688,855, filed on Aug. 29, 2024.

(51) Int. Cl. H10B 80/00; H01L 23/00; H01L 23/522; H01L 25/065

(52) U.S. Cl. CPC H10B 80/00

(57) ABSTRACT

A device comprising a memory device comprising a first memory chip comprising a first memory portion; and a first processor in memory portion, wherein the first processor in memory portion includes a first plurality of logic cells and at least one first capacitor; and a second memory chip coupled to the first memory chip.

### CROSS-REFERENCE TO RELATED APPLICATION

This application claims priority to and the benefit of U.S. Provisional Application Ser. No. 63/688,855, filed in the United States Patent and Trademark Office on Aug. 29, 2024, the entire content of which is incorporated herein by reference as if fully set forth below in its entirety and for all applicable purposes.

### FIELD

Various features relate to packages with substrates and semiconductor chips.

### BACKGROUND

A package may include a substrate and semiconductor chips. These components are coupled together to provide a package that may perform various electrical functions. There is an ongoing need to provide better performing packages, including packages with improved thermal performances and/or electrical performances. Moreover, there is also an ongoing need to reduce the overall size of the packages.

### SUMMARY

Various features relate to packages with substrates and semiconductor chips.

One example provides a device comprising a memory device comprising a first memory chip comprising a first memory portion; and a first processor in memory portion, wherein the first processor in memory portion includes a first plurality of logic cells and at least one first capacitor; and a second memory chip coupled to the first memory chip.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary block diagram of a logic chip.

FIG. 2 illustrates an exemplary diagram of a package that includes a stack of chips.

FIG. 3 illustrates an exemplary diagram of a package that includes a stack of chips.

FIG. 4 illustrates an exemplary cross sectional profile view of a semiconductor chip.

FIG. 5 illustrates an exemplary cross sectional profile view of a memory device comprising memory chips.

FIG. 6 illustrates an exemplary cross sectional plan view of a chip with a memory portion and a processor in memory portion.

FIG. 7 illustrates an exemplary cross sectional profile view of a capacitor.

FIG. 8 illustrates an exemplary cross sectional profile view of a capacitor.

FIGS. 9A-9B illustrate an exemplary sequence for fabricating a memory device with a memory portion and processor in memory portion.

FIG. 10 illustrates an exemplary sequence for fabricating a memory device with a memory portion and processor in memory portion.

FIG. 11 illustrates an exemplary cross sectional profile view of a package that includes a chip and a stack of chips.

FIGS. 12A-12B illustrate an exemplary sequence for fabricating a package comprising a chip and a stack of chips.

FIG. 13 illustrates an exemplary flow chart of a method for fabricating a package comprising a chip and a stack of chips.

FIGS. 14A-14F illustrate an exemplary sequence for fabricating a capacitor.

FIG. 15 illustrates an exemplary flow chart of a method for fabricating a capacitor.

FIG. 16 illustrates an exemplary flow chart of a method for fabricating a chip with a capacitor.

FIGS. 17A-17C illustrate an exemplary sequence for fabricating a chip with a capacitor.

FIG. 18 illustrates an exemplary flow chart of a method for fabricating a chip with a capacitor.

FIG. 19 illustrates an exemplary cross sectional profile view of a semiconductor chip.

FIG. 20 illustrates a block diagram showing an exemplary wireless communications system in which a configuration of the disclosure may be advantageously

FIG. 21 illustrates a block diagram illustrating a design workstation used for circuit, layout, and logic design of a semiconductor component, such as the disclosed dynamic random-access memory (DRAM) cell array micro-structure.

FIG. 22 illustrates various electronic devices that may integrate a die, an electronic circuit, a semiconductor chip, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a device comprising a memory device comprising a first memory chip comprising a first memory portion; and a first processor in memory portion, wherein the first processor in memory portion includes a first plurality of logic cells and at least one first capacitor; and a second memory chip coupled to the first memory chip.

Memory is a vital component for processing devices, wireless communications devices, etc. For example, a cell phone may integrate memory as part of an application processor, such as a system-on-chip (SoC) including a central processing unit (CPU), a graphics processing unit (GPU), and a neural processing unit (NPU). Successful operation of some wireless applications depends on the availability of a high-capacity and low-latency memory solution for scalability of processor workload. A semiconductor memory device solution for providing a high-capacity, low-latency, and high-bandwidth memory is an existing goal for system designers.

Semiconductor memory devices include, for example, dynamic random-access memory (DRAM). A DRAM memory cell includes one transistor and one capacitor, thereby providing a high degree of integration. In practice, memory intensive applications (e.g., artificial intelligence (AI)) require extensive amounts of DRAM. A high-bandwidth, high-capacity DRAM memory stack is an important solution for enabling AI. Power integrity for a high-speed double data rate (DDR) interface and processor-in-memory (PIM) operation is challenging especially when utilizing a three-dimensional (3D) stacked high-bandwidth DRAM structure. Therefore, a solution for providing improved power integrity when using when utilizing a 3D stacked high-bandwidth DRAM structure is desired.

Various aspects of the present disclosure are directed to an on-die capacitor integration utilizing a thick oxide above peripheral logic areas of a memory cell array. The process flow for fabrication of the on-die capacitor integration utilizing thick oxide above peripheral logic areas includes integrated circuit (IC) process technology for on-die capacitor formation. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an IC device. As described, the term “chiplet” may refer to an integrated circuit block, a functional circuit block, or other like circuit block specifically designed to work with other similar chiplets to form a larger, more complex chiplet architecture. The terms “substrate,” “wafer,” and “laminate” may be used interchangeably. Similarly, the terms “chip,” “chiplet,” and “die” may be used interchangeably.

Various aspects of the present disclosure are directed to an on-die capacitor integration utilizing a thick oxide layer above peripheral logic areas of a memory cell array. In various aspects of the present disclosure, an on-die capacitor is formed above a logic area adjacent to a memory cell area of a memory die. An empty (or vacant) oxide area above the logic area is utilized to form capacitors, such as trench capacitors, stacked capacitors, or other like capacitance structures in the empty oxide area. The on-die capacitors may be utilized in place of conventional package capacitors.

### Exemplary Package Comprising a Stack of Chips

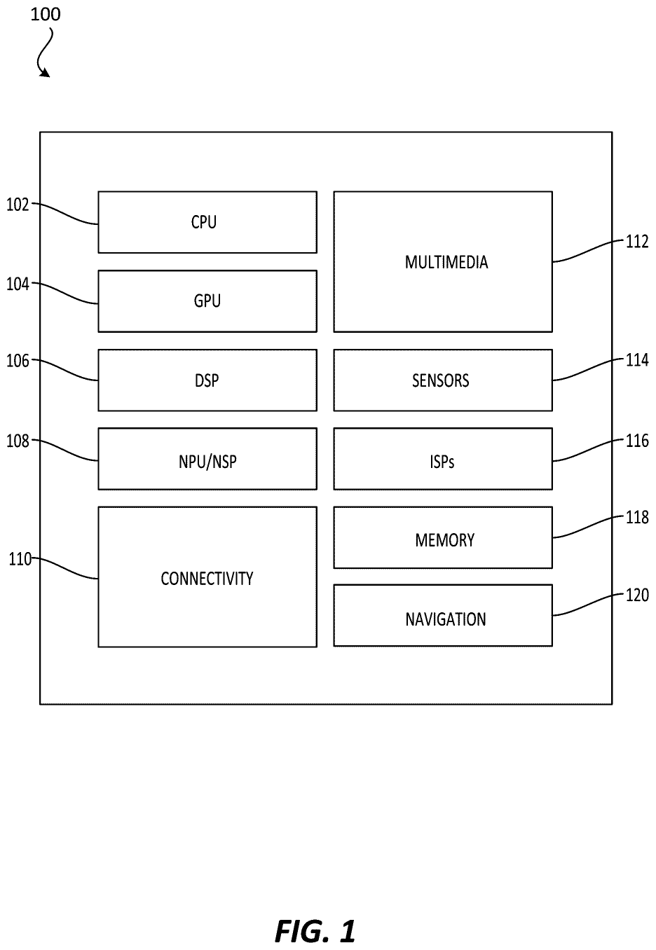

FIG. 1 illustrates an example implementation of a host system-on-chip (SoC) 100, which includes an on-die capacitor integration utilizing a thick oxide layer above peripheral logic areas of a memory cell array, in accordance with certain aspects of the present disclosure. The host SoC 100 includes processing blocks tailored to specific functions, such as a connectivity block 110. The connectivity block 110 may include sixth generation (6G) connectivity, fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system (GPS), and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set.

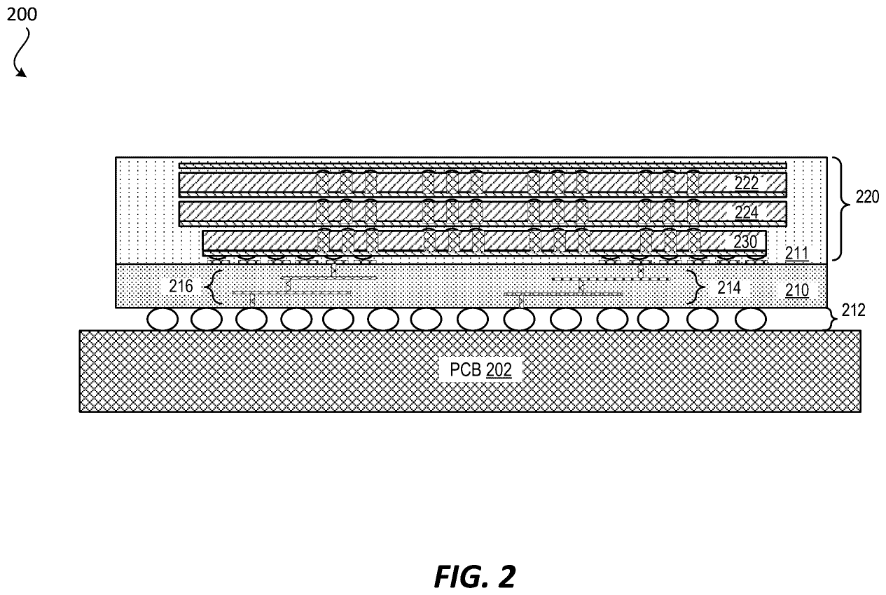

FIG. 2 illustrates an exemplary cross-sectional view of a stacked chip package 200 of a fusion bonded three-dimensional (3D) stacked wide-input/output (IO) memory of the host system-on-chip (SoC) 100 of FIG. 1. Representatively, the stacked chip package 200 includes a printed circuit board (PCB) 202 connected to a package substrate 210 with interconnects 212. In this configuration, the package substrate 210 includes conductive layers 214 and 216 (e.g., interconnects). Above the package substrate 210 is a 3D chip stack 220, including stacked chips 222, 224, and 230, encapsulated by mold compound 211 (e.g., encapsulation layer). In one aspect of the present disclosure, the chip 230 is a fusion bonded three-dimensional (3D) stacked wide-input/output (IO) memory of the host SoC 100 of FIG. 1.

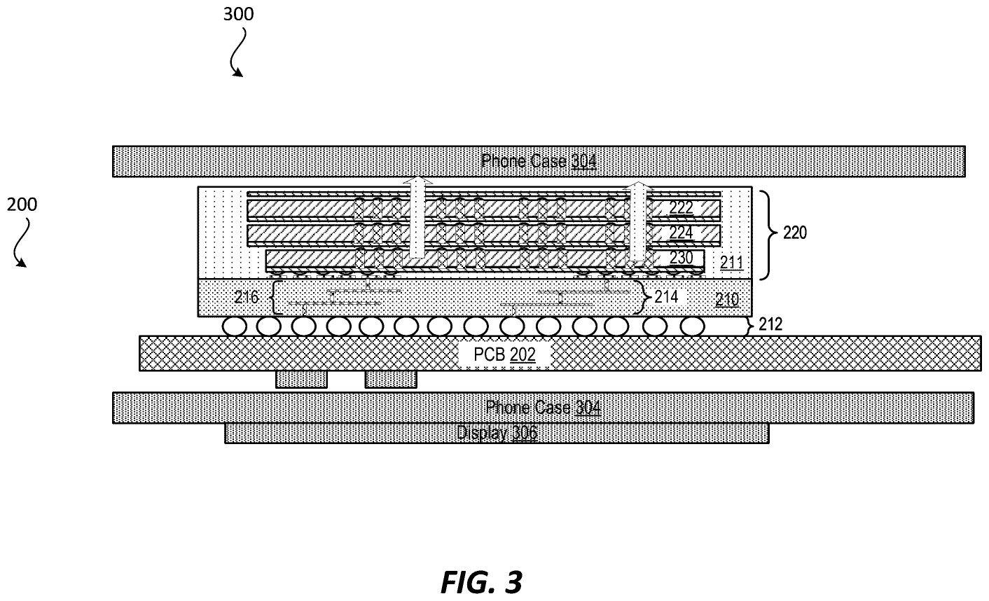

FIG. 3 illustrates an exemplary cross-sectional view illustrating the stacked chip package 200 of FIG. 2, incorporated into a compute device 300, according to one aspect of the present disclosure. As described, the compute device 300 may include, but is not limited to, a smartphone, tablet, handheld device, or other limited form factor device configured for 5G NR/6G communications. Representatively, the stacked chip package 200 is within a case 304, including a display 306.

In practice, memory intensive applications (e.g., artificial intelligence (AI)) require extensive amounts of DRAM. High external bandwidth memory is important for AI evolution. External bandwidth, however, is related to the total number of physical pins that exit from a DRAM structure. One solution for increasing the number of pin-outs is increasing DRAM die size to accommodate physical pin placement and routing. Unfortunately, a total memory capacity in a given x-y form factor is expected to continually decrease. Conventional, customized DRAM structures increase the external bandwidth by providing more pin-outs, but those solutions incur severe trade-offs between bandwidth and total memory capacity per x-y form factor size. In various aspects of the present disclosure, a fusion bonded 3D stacked wide-IO memory is integrated in the stacked chip package 200 to support 3D chip stacking.

### Exemplary Semiconductor Chip

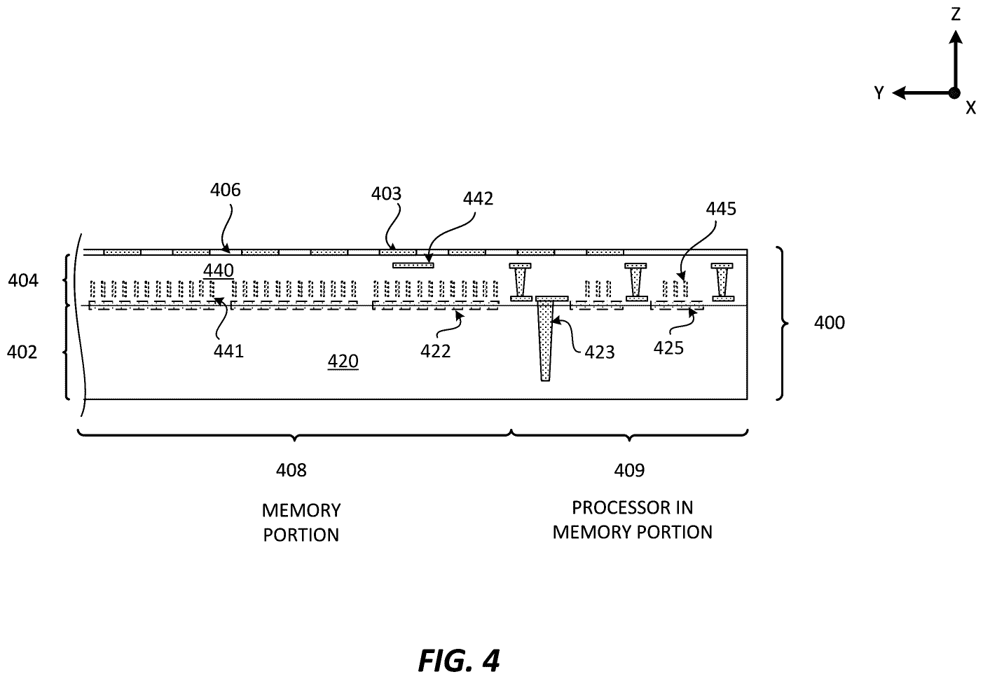

FIG. 4 illustrates a cross sectional profile view of a chip 400. The chip 400 may be a semiconductor chip. The chip 400 may be an integrated circuit (IC) chip. In some implementations, the chip 400 may be configured as a memory chip.

The chip 400 includes a die substrate portion 402, a die interconnection portion 404, a plurality of pad interconnects 403, and/or a passivation layer 406. The passivation layer 406 may be optional.

The die substrate portion 402 includes a die substrate 420 and an active region 422. The die substrate 420 may include silicon (Si). The active region 422 may be formed in the die substrate 420 and/or a surface of the die substrate 420. The active region 422 may include a plurality of logic cells and/or a plurality of transistors. One or more transistors may define a logic cell. The plurality of logic cells may include functioning logic cells when the integrated device is in operation. The plurality of transistors may include functioning transistors. Different implementations may use different types of transistors, such as a field effect transistor (FET), planar FET, finFET, and a gate all around FET. In some implementations, a front end of line (FEOL) process may be used to fabricate the plurality of cells and/or transistors in and/or over the die substrate 420. In some implementations, the die substrate portion 402 may include a plurality of through substrate via interconnects 423 that extend through at least part of the die substrate 420. A metallization portion (not shown) may be coupled to the die substrate 420. The metallization portion may be a back side metallization portion. The metallization portion may include a plurality of metallization interconnects (e.g., back side metallization interconnects) that are coupled to the through substrate via interconnects 423 that extend through at least part of the die substrate 420. Although not shown, a passivation layer (e.g., similar to the passivation layer 406) may be formed on the back side of the chip 400. The passivation layer may be formed on the back side of the die substrate 420.

The die interconnection portion 404 is coupled to the die substrate portion 402. For example, the die interconnection portion 404 is coupled to the die substrate 420. The die interconnection portion 404 includes at least one dielectric layer 440, a plurality of capacitors 441 and a plurality of die interconnects 442. The die interconnection portion 404 may be configured to be electrically coupled to the active region 422. For example, the plurality of capacitors 441 and/or the plurality of die interconnects 442 may be configured to be electrically coupled to the active region 422. In some implementations, the plurality of capacitors 441 and/or the plurality of active region 422 may be configured a memory portion and/or a memory block. Thus, the plurality of capacitors 441 and/or the plurality of die interconnects 442 may be configured to be electrically coupled to the plurality of logic cells and/or plurality of transistors. In some implementations, the plurality of capacitors 441 may include metal-oxide-semiconductor (MOS) capacitors, p-n junction capacitors, metal-insulator-metal (MIM) capacitors, poly-to-poly capacitors, metal-oxide-metal (MOM) capacitors, trench capacitors, integrated stack capacitors, and/or other like capacitor structures. Capacitors are passive elements used in integrated circuits for storing an electrical charge. For example, parallel plate capacitors are often made using plates or structures that are conductive with an insulating material between the plates. In some implementations, a back end of line (BEOL) process may be used to fabricate the die interconnection portion 404. The die interconnection portion 404 may be a BEOL die interconnection portion. The plurality of die interconnects 442 may include copper (Cu). The die interconnection portion 404 may be formed over the die substrate portion 402.

The plurality of pad interconnects 403 are coupled to the die interconnection portion 404. The plurality of pad interconnects 403 may be coupled to the plurality of die interconnects 442. The plurality of pad interconnects 403 may include Aluminum (Al).

The passivation layer 406 is coupled to the die interconnection portion 404. The passivation layer 406 may be formed and coupled to a surface of the die interconnection portion 404. The passivation layer 406 may be coupled to and touch the at least one dielectric layer 440. The passivation layer 406 may be formed and coupled to part of the plurality of pad interconnects 403. In some implementations, the passivation layer 406 may include silicon nitride (SiN). However, different implementations may use different materials for the passivation layer 406. The passivation layer 406 may include a different material from the at least one dielectric layer 440.

In some implementations, the chip 400 may include a plurality of via interconnects 423. The plurality of via interconnects 423 may extend through at least part of the die substrate 420 and/or at least part of the at least one dielectric layer 440. In some implementations, some via interconnects from the plurality of via interconnects 423 may extend through at least part of the die substrate 420 and some via interconnects from the plurality of via interconnects 423 may extend through at least part of the at least one dielectric layer 440.

The chip 400 includes a front side and a back side. The front side of the chip 400 may be the side of the chip 400 that includes the plurality of pad interconnects 403 and/or the passivation layer 406. The back side of the chip 400 may be the side of the chip 400 that includes the die substrate 420. The chip 400 may be a singulated chip from a wafer comprising several uncut chips.

The chip 400 includes a memory portion 408 and a processor in memory portion 409. The memory portion 408 includes the active region 422 and the plurality of capacitors 441. In one example, the plurality of capacitors 441 may be coupled to bit lines of the active region 422. The processor in memory portion 409 includes an active region 425 and a plurality of capacitors 445. The active region 425 is configured to provide logic functions and/or processor functions (e.g., CPU function, GPU function, NPU function). The plurality of capacitors 445 may be located in the at least one dielectric layer 440. The at least one dielectric layer 440 may include an oxide (e.g., oxide layer). In some implementations, the at least one dielectric layer 440 may include silicon dioxide (SiO₂) or silicon nitride (SiN). In some implementations, the plurality of capacitors 445 may include metal-oxide-semiconductor (MOS) capacitors, p-n junction capacitors, metal-insulator-metal (MIM) capacitors, poly-to-poly capacitors, metal-oxide-metal (MOM) capacitors, trench capacitors, integrated stack capacitors, and/or other like capacitor structures. Capacitors are passive elements used in integrated circuits for storing an electrical charge. For example, parallel plate capacitors are often made using plates or structures that are conductive with an insulating material between the plates. By positioning the capacitors closer to the active region 425, signal integrity can be improved, which helps improve the performance of the chip 400. Moreover, utilizing a space that would otherwise not be used, can help reduce the overall size of the package, since capacitors that may have been needed or added on outside of the chip 400 may no longer be needed in the package comprising the chip 400. A processor in memory portion may include one or more processor in memory portions.

A processor in memory (PIM) architecture supplies computation and processing capability near memory instead of transferring significant amounts of data to/from a computing unit. PIM architectures may operate at the cell level of a data array, at the sense amplifier/row-buffer level, and/or near memory banks that can execute a subset of CPU instructions. Additionally, PIM architectures may be designed for specific applications, including AI applications, such as deep neural network (DNN) applications, or other like AI functions. Such implementations of PIM architectures, however, incur power integrity issues. Therefore, a solution for providing power integrity when utilizing a high-bandwidth, high-capacity 3D DRAM structure incorporating PIM functionality is desired.

### Exemplary Memory Device

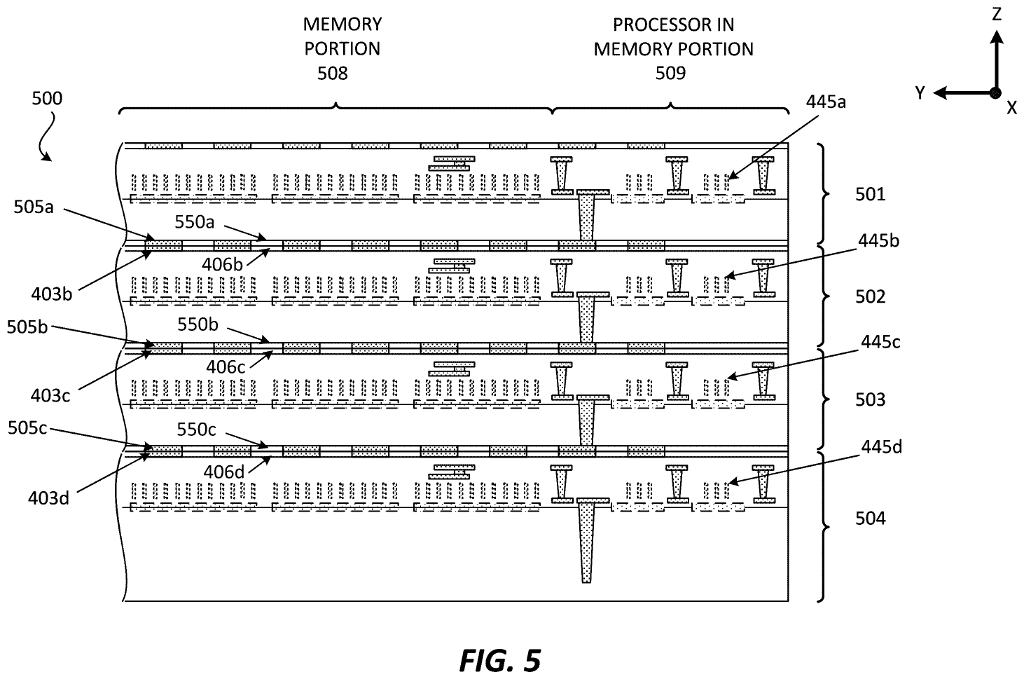

FIG. 5 illustrates a cross sectional profile view of a memory device 500. The memory device 500 may be a stack of chips (e.g., stack of memory chips). The memory device 500 includes a chip 501, a chip 502, a chip 503 and a chip 504. The chip 501, the chip 502, the chip 503 and/or the chip 504 may similar to the chip 400, and may this include similar components to the chip 400. The memory device 500 may include a different number of chips (e.g., memory chips), such as more than four chips or less than four chips. The memory device 500 includes a memory portion 508 and a processor in memory portion 509. The memory portion 508 may be similar to the memory portion 408 of the chip 400. The processor in memory portion 509 may be similar to the processor in memory portion 409 of the chip 400.

The chip 501 may include a die substrate portion 402a, a die substrate 420a, a die interconnection portion 404a, a plurality of pad interconnects 403a and a passivation layer 406a. The chip 502 may include a die substrate portion 402b, a die substrate 420b, a die interconnection portion 404b, a plurality of pad interconnects 403b, a passivation layer 406b, a passivation layer 550b and a plurality of back side interconnects 505b. The chip 503 may include a die substrate portion 402c, a die substrate 420c, a die interconnection portion 404c, a plurality of pad interconnects 403c, a passivation layer 406c, a passivation layer 550c and a plurality of back side interconnects 505c. The chip 504 may include a die substrate portion 402d, a die substrate 420d, a die interconnection portion 404d, a plurality of pad interconnects 403d, a passivation layer 406d, a passivation layer 550d and a plurality of back side interconnects 505d. The chip 501 includes a memory portion 408a and a processor in memory portion 409a.

The chip 502 is coupled to the chip 501. For example, a front side of the chip 502 may be coupled to and touching a back side of the chip 501. The chip 502 may be coupled to the chip 501 through hybrid bonding. Hybrid bonding may include metal to metal bonding, such as copper to copper bonding. For example, the plurality of back side interconnects 505a of the chip 501 may be coupled to and touching the plurality of pad interconnects 403b of the chip 502. The chip 502 includes a memory portion 408b and a processor in memory portion 409b. The passivation layer 550a of the chip 501 may be coupled to the passivation layer 406b of the chip 502.

The chip 503 is coupled to the chip 502. For example, a front side of the chip 503 may be coupled to and touching a back side of the chip 502. The chip 503 may be coupled to the chip 502 through hybrid bonding. Hybrid bonding may include metal to metal bonding, such as copper to copper bonding. For example, the plurality of back side interconnects 505b of the chip 502 may be coupled to and touching the plurality of pad interconnects 403c of the chip 503. The chip 503 includes a memory portion 408c and a processor in memory portion 409c. The passivation layer 550b of the chip 502 may be coupled to the passivation layer 406c of the chip 503.

The chip 504 is coupled to the chip 503. For example, a front side of the chip 504 may be coupled to and touching a back side of the chip 503. The chip 504 may be coupled to the chip 503 through hybrid bonding. Hybrid bonding may include metal to metal bonding, such as copper to copper bonding. For example, the plurality of back side interconnects 505c of the chip 503 may be coupled to and touching the plurality of pad interconnects 403d of the chip 504. The chip 504 includes a memory portion 408d and a processor in memory portion 409d. The passivation layer 550c of the chip 503 may be coupled to the passivation layer 406d of the chip 504.

In some implementations, the memory portion 408a may vertically overlap with the memory portion 408b, the memory portion 408c and/or the memory portion 408d. In some implementations, the processor in memory portion 409a may vertically overlap with the processor in memory portion 409b, the processor in memory portion 409c and/or the processor in memory portion 409d.

The configuration of memory device 500 helps provide a memory device with a compact form factor (e.g., the reduced thickness), while reducing and/or minimizing the distance the signals have to travel to different chips of the memory device 500.

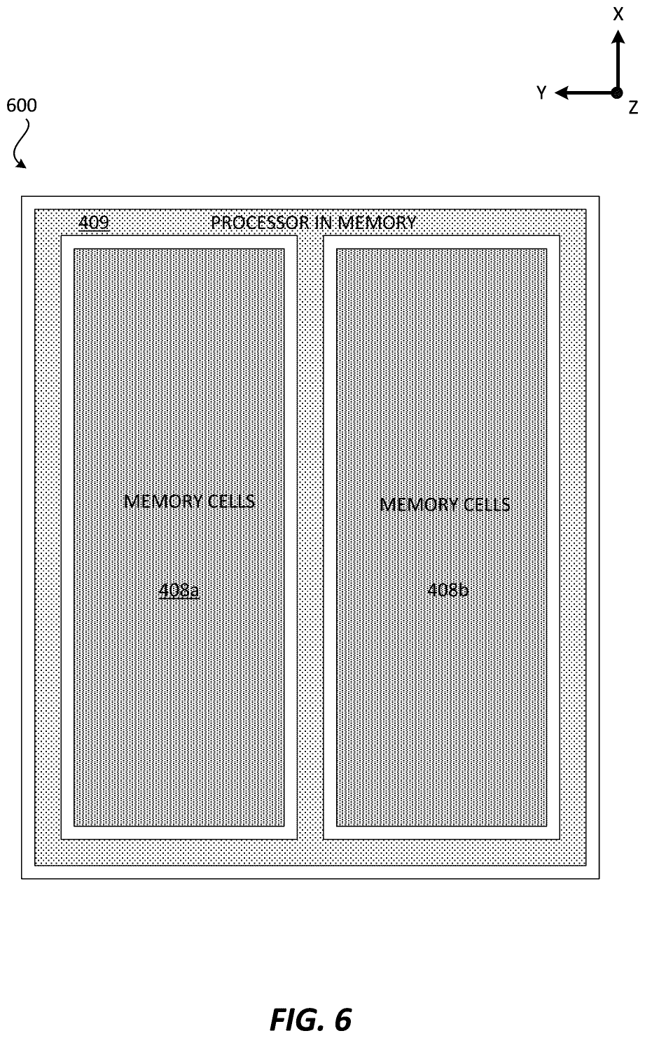

FIG. 6 illustrates a plan view of the chip 600. The chip 600 may represent the chip 400. As shown in FIG. 6, the chip 600 includes a memory portion 408a, a memory portion 408b and a processor in memory portion 509. A part of the processor in memory portion 409 is located laterally between the memory portion 408a and the memory portion 408b. A part of the processor in memory portion 409 may laterally surround the memory portion 408a. A part of the processor in memory portion 409 may laterally surround the memory portion 408b. A part of the processor in memory portion 409 may be located along the periphery and/or the edges (e.g., first edge, second edge, third edge, fourth edge) of the chip 600.

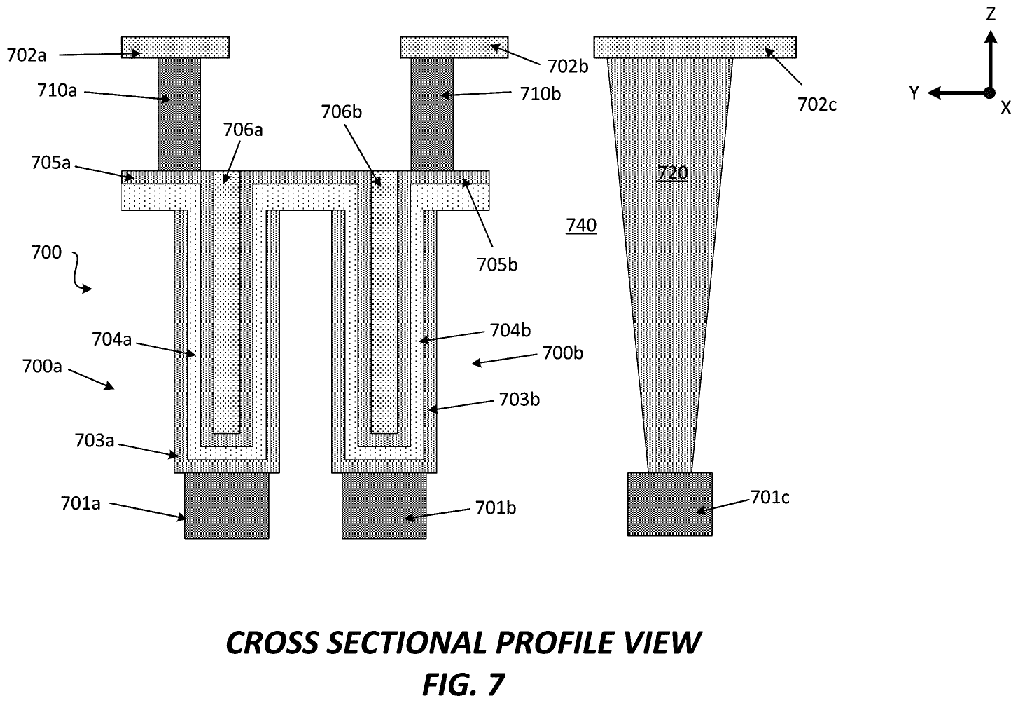

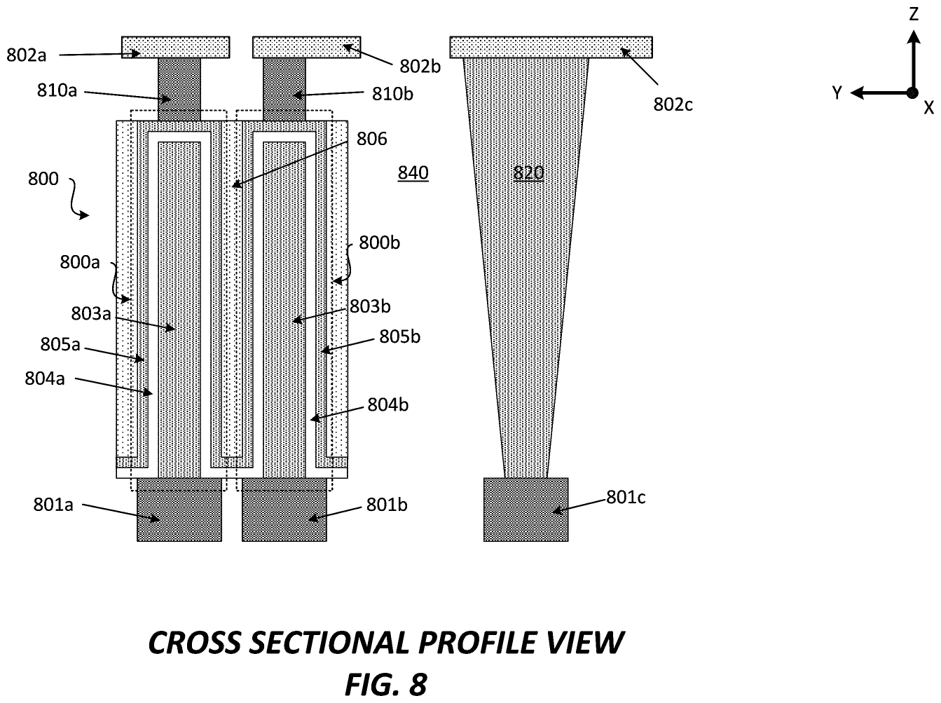

Different implementations may have different capacitors designs. FIGS. 7 and 8 illustrate examples of capacitors that may be located in a processor in memory portion (e.g., 409) of a chip.

FIG. 7 illustrates a plurality of capacitors 700 that are implemented in at least one dielectric layer (e.g., 740) of a chip. In some implementations, the plurality of capacitors 700 may represent the plurality of capacitors 445. The plurality of capacitors 700 includes a capacitor 700a and a capacitor 700b. The plurality of capacitors 700 may include a plurality of deep trench capacitors.

The capacitor 700a includes a first electrode 703a, a capacitor dielectric layer 704a, and a second electrode 705a. The capacitor dielectric layer 704a may be located between the first electrode 703a and the second electrode 705a. The first electrode 703a may be a bottom electrode and the second electrode 705a may be a top electrode. In some implementations, the first electrode 703a may include heavily doped polysilicon or tungsten (W). In some implementations, the capacitor dielectric layer 704a may be a high K dielectric layer, such as zirconium dioxide (ZrO₂) and oxide-nitride-oxide (ONO). In some implementations, the second electrode 705a may include titanium nitride (TiN). However, it is noted that different materials may be used for the first electrode 703a, the second electrode 705a and/or the capacitor dielectric layer 704a. In some implementations, there may be a filler 706a. The filler 706a may include a heavily doped polysilicon or tungsten (W) between different portions of the second electrode 705a. The first electrode 703a may be coupled to and touch an interconnect 701a. The second electrode 705a may be coupled to and touch an interconnect 710a. The interconnect 702a is coupled to the interconnect 710a.

The capacitor 700b includes a first electrode 703b, a capacitor dielectric layer 704b, and a second electrode 705b. The capacitor dielectric layer 704b may be located between the first electrode 703b and the second electrode 705b. The first electrode 703b may be a bottom electrode and the second electrode 705b may be a top electrode. In some implementations, the first electrode 703b may include heavily doped polysilicon or tungsten (W). In some implementations, the capacitor dielectric layer 704b may be a high K dielectric layer, such as zirconium dioxide (ZrO₂) and oxide-nitride-oxide (ONO). In some implementations, the second electrode 705b may include titanium nitride (TiN). However, it is noted that different materials may be used for the first electrode 703b, the second electrode 705b and/or the capacitor dielectric layer 704b. In some implementations, there may be a filler 706b. The filler 706b may be a heavily doped polysilicon or tungsten (W) between different portions of the second electrode 705b. The first electrode 703b may be coupled to and touch an interconnect 701b. The second electrode 705b may be coupled to and touch an interconnect 710b. The interconnect 702b is coupled to the interconnect 710b.

FIG. 7 also illustrates a via interconnect 720. The via interconnect is located in the dielectric layer 740. The via interconnect 720 is located laterally adjacent to the plurality of capacitors 700. The via interconnect 720 is coupled to the interconnect 701c and the interconnect 702c. In some implementations, the interconnect 701c may be located on a first die interconnect metal layer of the chip, and the interconnect 702c may be located on a second die interconnect metal layer of the chip. Thus, in some implementations, the plurality of capacitors 700 may be located between the first die interconnect metal layer of the chip and the second die interconnect metal layer of the chip.

FIG. 8 illustrates a plurality of capacitors 800 that are implemented in a dielectric layer (e.g., 840) of a chip. In some implementations, the plurality of capacitors 800 may represent the plurality of capacitors 445. The plurality of capacitors 800 includes a capacitor 800a and a capacitor 800b. The plurality of capacitors 800 may include a plurality of deep trench capacitors. The plurality of capacitors 800 may have a different configuration from the plurality of capacitors 700.

The capacitor 800a includes a first electrode 803a, a capacitor dielectric layer 804a, and a second electrode 805a. The capacitor dielectric layer 804a may be located between the first electrode 803a and the second electrode 805a. The first electrode 803a may be a bottom electrode and the second electrode 805a may be a top electrode. In some implementations, the first electrode 803a may include heavily doped polysilicon or tungsten (W). In some implementations, the capacitor dielectric layer 804a may be a high K dielectric layer, such as zirconium dioxide (ZrO₂) and oxide-nitride-oxide (ONO). In some implementations, the second electrode 805a may include titanium nitride (TiN). However, it is noted that different materials may be used for the first electrode 803a, the second electrode 805a and/or the capacitor dielectric layer 804a. In some implementations, there may be a filler 806a. The filler 806a may be a heavily doped polysilicon or tungsten (W) between different portions of the second electrode 805a. The first electrode 803a may be coupled to and touch an interconnect 801a. The second electrode 805a may be coupled to and touch an interconnect 810a. The interconnect 802a is coupled to the interconnect 810a.

The capacitor 800b includes a first electrode 803b, a capacitor dielectric layer 804b, and a second electrode 805b. The capacitor dielectric layer 804b may be located between the first electrode 803b and the second electrode 805b. The first electrode 803b may be a bottom electrode and the second electrode 805b may be a top electrode. In some implementations, the first electrode 803b may include heavily doped polysilicon or tungsten (W). In some implementations, the capacitor dielectric layer 804b may be a high K dielectric layer, such as zirconium dioxide (ZrO₂) and oxide-nitride-oxide (ONO). In some implementations, the second electrode 805b may include titanium nitride (TiN). However, it is noted that different materials may be used for the first electrode 803b, the second electrode 805b and/or the capacitor dielectric layer 804b. In some implementations, there may be a filler 806b. The filler 806b may be a heavily doped polysilicon or tungsten (W) between different portions of the second electrode 805b. The first electrode 803b may be coupled to and touch an interconnect 801b. The second electrode 805b may be coupled to and touch an interconnect 810b. The interconnect 802b is coupled to the interconnect 810b.

FIG. 8 also illustrates a via interconnect 820. The via interconnect is located in the dielectric layer 840. The via interconnect 820 is located laterally adjacent to the plurality of capacitors 800. The via interconnect 820 is coupled to the interconnect 801c and the interconnect 802c. In some implementations, the interconnect 801c may be located on a first die interconnect metal layer of the chip, and the interconnect 802c may be located on a second die interconnect metal layer of the chip. Thus, in some implementations, the plurality of capacitors 800 may be located between the first die interconnect metal layer of the chip and the second die interconnect metal layer of the chip. It is noted that the material listed above for the various components of a capacitor are exemplary. Different implementations may use different materials for the different components of the capacitors (e.g., plurality of capacitors 700, plurality of capacitors 800).

A memory chip can includes a bus interconnect unit, a processing unit, a physical layer unit, a data correction unit, a test unit. A processing unit may be a unit of the chip configured to process input and/or output data. A bus interconnect unit may be a unit of the chip configured to manage where and/or how data travels between different units in the chip. A physical layer unit may be a unit of the chip configured to manage how data (e.g., input/output signals) enters and/or leaves the chip. A memory unit or a memory block may be a unit of the chip configured to store data. A data correction unit may be a unit of the chip configured to check data that is stored and/or retrieved from the memory unit or memory block. The test unit is a unit of the chip that is configured to check that the memory units work probably.

### Exemplary Sequence for Fabricating a Memory Device

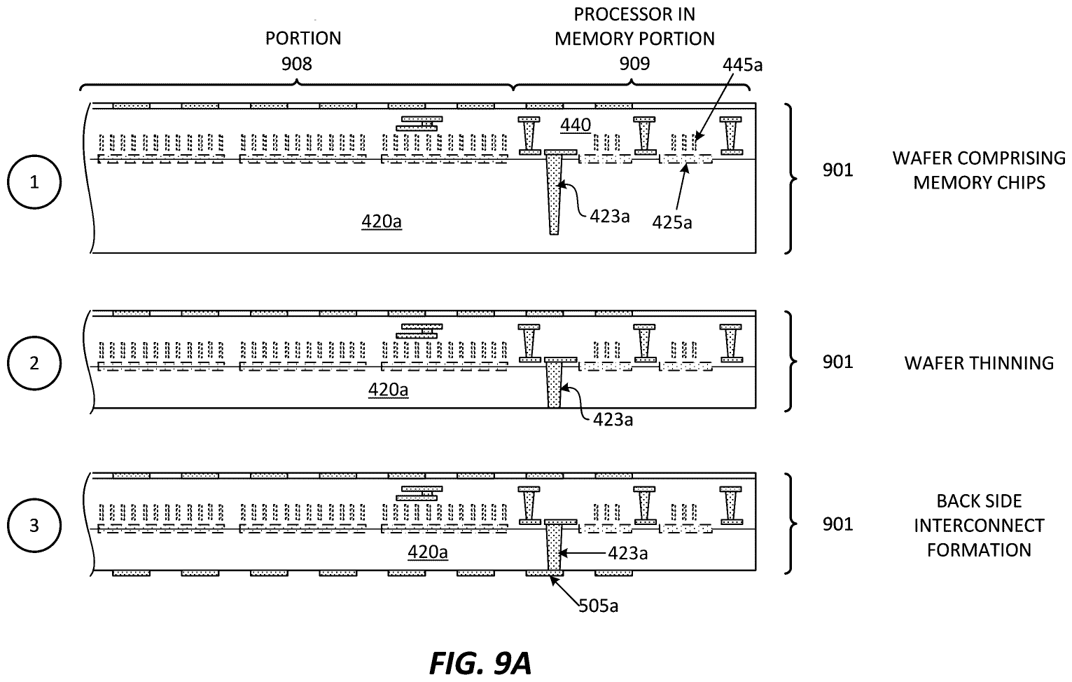

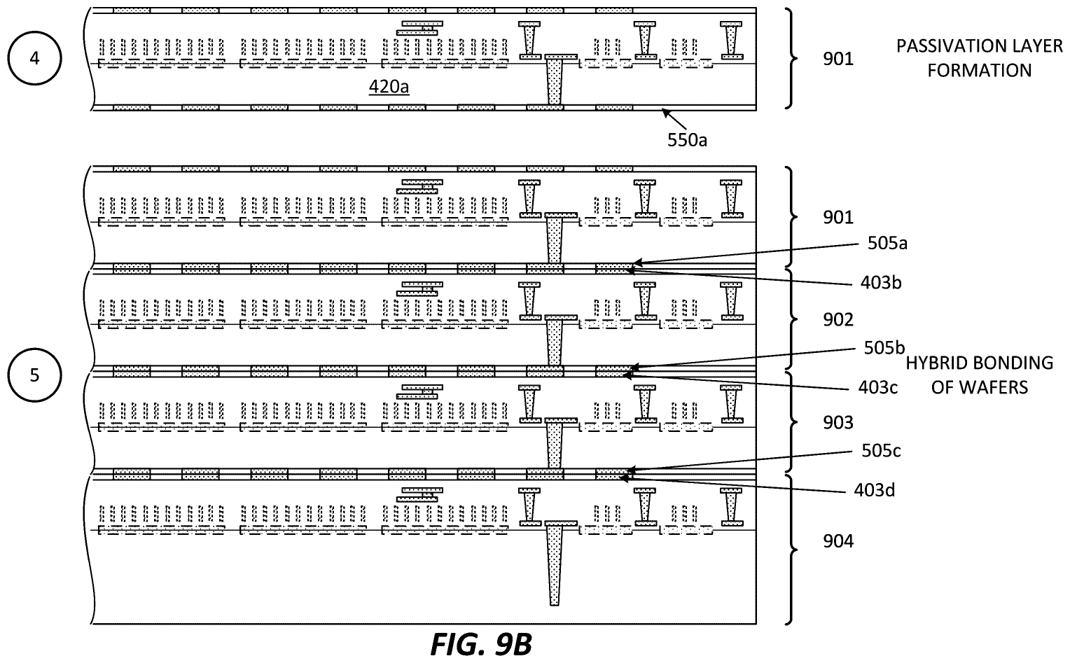

In some implementations, fabricating a memory device includes several processes. FIGS. 9A-9B illustrate an exemplary sequence for providing or fabricating a memory device. In some implementations, the sequence of FIGS. 9A-9B may be used to provide or fabricate the memory device 500. However, the process of FIGS. 9A-9B may be used to fabricate any memory devices with different numbers of memory chips.

It should be noted that the sequence of FIGS. 9A-9B may combine one or more stages in order to simplify and/or clarify the sequence for providing or fabricating a memory device. In some implementations, the order of the processes may be changed or modified. In some implementations, one or more of processes may be replaced or substituted without departing from the scope of the disclosure.

Stage 1, as shown in FIG. 9A, illustrates a state after a wafer 901 (e.g., first wafer) is provided. The wafer 901 may include uncut chips (e.g., uncut memory chips). The wafer 901 may include uncut chips that are similar to the chip 400. The wafer 901 may include uncut chips with a memory portion 908 and a processor in memory portion 909. The processor in memory portion includes a plurality of capacitors (e.g., 445a).

Stage 2 illustrates a state after portions of the die substrate 420a is removed. A thinning process may be used to remove and/or thin the die substrate 420a. Removing a portion of the die substrate 420a may expose the plurality of via interconnects 423a.

Stage 3 illustrates a state after a plurality of back side interconnects 505a are formed and on the back side of the die substrate 420a. The plurality of back side interconnects 505a are coupled to the plurality of via interconnects 423a. The plurality of back side interconnects 505a may be formed through a plating process.

Stage 4, as shown in FIG. 9B, illustrates a state after a passivation layer 550a is formed on the back side of the die substrate 420a. A lamination process and/or a deposition process may be used to form the passivation layer 550a.

A wafer 902, a wafer 903 and a wafer 904 may be provided and fabricated in a similar manner as described above for the wafer 901.

Stage 5 illustrates a state after the wafer 901, the wafer 902, the wafer 903 and the wafer 904 are coupled together. In some implementations, a back side of the wafer 901 may be coupled to a front side of the wafer 902 through a hybrid bonding process. In some implementations, a back side of the wafer 902 may be coupled to a front side of the wafer 903 through a hybrid bonding process. In some implementations, a back side of the wafer 903 may be coupled to a front side of the wafer 904 through a hybrid bonding process. It is noted that different implementations may couple the wafers together differently. In some implementations, a front side of a wafer may be coupled to a front side of another wafer. In some implementations, a back side of a wafer may be coupled to a back side of another wafer. FIG. 5 illustrates an example of how hybrid bonding may be used to couple various interconnects together.

Once the wafers are coupled together, a singulation process may be used to form a plurality of memory devices 1010 with chips that include a memory portion and a processor in memory portion, where the processor in memory portion of a chip includes a plurality of capacitors.

### Exemplary Sequence for Fabricating a Memory Device

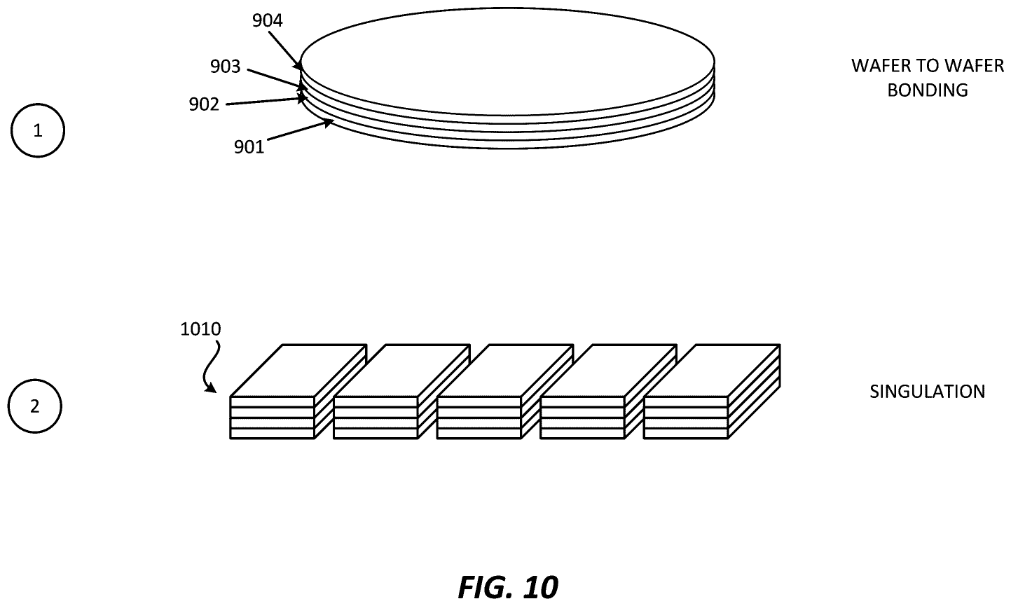

In some implementations, fabricating a memory device includes several processes. FIG. 10 illustrates an exemplary sequence for providing or fabricating a memory device. In some implementations, the sequence of FIG. 10 may be used to provide or fabricate the memory device 500. However, the process of FIG. 10 may be used to fabricate any memory devices with different numbers of memory chips.

It should be noted that the sequence of FIG. 10 may combine one or more stages in order to simplify and/or clarify the sequence for providing or fabricating a memory device. In some implementations, the order of the processes may be changed or modified. In some implementations, one or more of processes may be replaced or substituted without departing from the scope of the disclosure.

Stage 1 illustrates a state after the wafer 901, the wafer 902, the wafer 903 and the wafer 904 are coupled together. In some implementations, a back side of the wafer 901 may be coupled to a front side of the wafer 902 through a hybrid bonding process. In some implementations, a back side of the wafer 902 may be coupled to a front side of the wafer 903 through a hybrid bonding process. In some implementations, a back side of the wafer 903 may be coupled to a front side of the wafer 904 through a hybrid bonding process. It is noted that different implementations may couple the wafers together differently. In some implementations, a front side of a wafer may be coupled to a front side of another wafer. In some implementations, a back side of a wafer may be coupled to a back side of another wafer.

Stage 2 illustrates a state after singulation of the wafer 901, the wafer 902, the wafer 903 and the wafer 904 to form a plurality of memory devices 1010. A saw process may be used to perform the singulation. The plurality of memory devices 1010 may include a memory device that is the same or similar to the memory device 500.

### Exemplary Package Comprising Memory Device

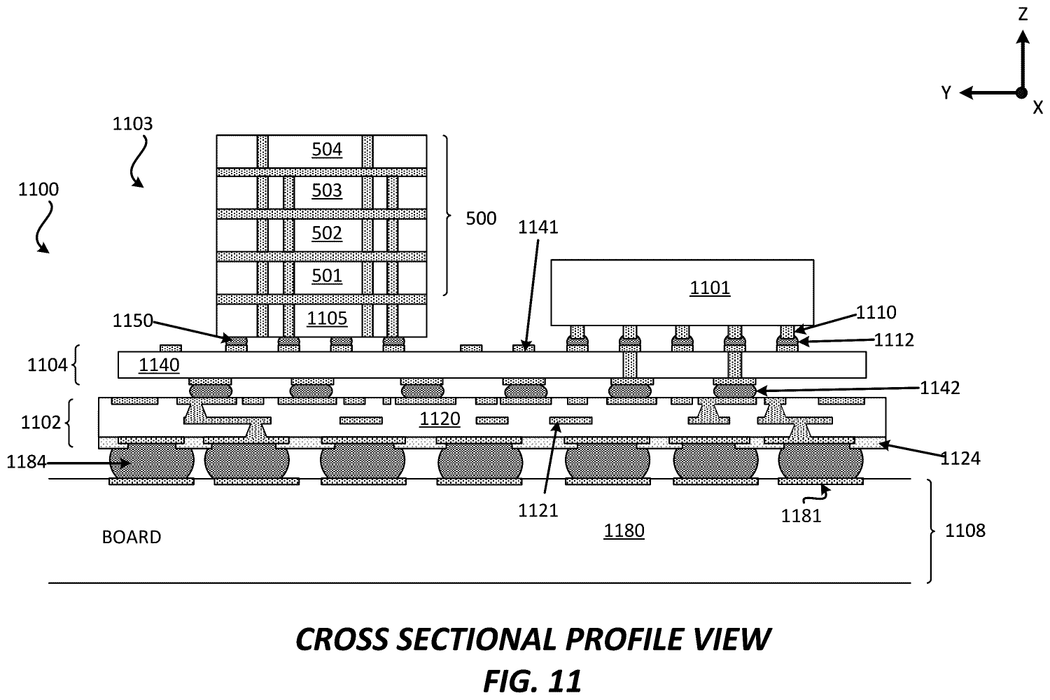

FIG. 11 illustrates a cross sectional profile view of a package 1100 that includes a stack of chips. The package 1100 may be coupled to a board 1108 through a plurality of solder interconnects 1184. The board 1108 may be a printed circuit board (PCB). The board 1108 may include at least one board dielectric layer 1180 and a plurality of board interconnects 1181. The package 1100 includes a chip 1101, a substrate 1102, a substrate 1104 and a stack of chips 1103.

The substrate 1102 may be a laminated substrate. The substrate 1102 includes at least one dielectric layer 1120, a plurality of interconnects 1121 and a solder resist layer 1124. In some implementations, the at least one dielectric layer 1120 can include prepreg. However, different implementations may use different materials for the at least one dielectric layer 1120. In some implementations, the substrate 1102 can be a coreless substrate, such as an embedded trace substrate. In some implementations, the substrate 1102 may be a core substrate. The substrate 1104 may be an interposer. The substrate 1104 may include at least one dielectric layer 1140 and a plurality of interconnects 1141. The at least one dielectric layer 1140 can include silicon or glass. However, different implementations may use different materials for the at least one dielectric layer 1140. The substrate 1104 may be coupled to the substrate 1102 through a plurality of solder interconnects 1142. The plurality of solder interconnects 1142 may be coupled to and touch the plurality of interconnects 1121 and the plurality of interconnects 1141. The substrate 1102 may be coupled to the board 1108 through a plurality of solder interconnects 1184. The plurality of solder interconnects 1184 may be coupled to and touch the plurality of the plurality of interconnects 1121 and the plurality of board

The chip 1101 may be coupled to the substrate 1104 through a plurality of pillar interconnects 1110 and a plurality of solder interconnects 1112. The plurality of solder interconnects 1112 may be coupled to and touch the plurality of pillar interconnects 1110 and the plurality of interconnects 1141. In some implementations, the plurality of pillar interconnects 1110 may be optional. In some implementations, the chip 1101 may include a logic chip and/or a logic die. The chip 1101 may include an application processor (AP), a central processing unit (CPU), a graphical processing unit (GPU) and/or neural processing unit (NPU). The chip 1101 can be implemented as a system on chip (SoC).

The stack of chips 1103 may be coupled to the substrate 1104 through a plurality of solder interconnects 1150. The plurality of solder interconnects 1150 may be coupled to the plurality of interconnects 1141 of the substrate 1104. The stack of chips 1103 may be laterally adjacent and/or laterally next to the chip 1101. The stack of chips 1103 may include a chip 1105 and the memory device 500. The memory device 500 may include a plurality of chips (e.g., memory chips) that may include a plurality of through substrate vias (TSVs). The plurality of through substrate vias (TSVs) can be a plurality of through silicon vias. A via can be a via interconnect (e.g., through substrate via interconnects, through silicon via interconnects). In some implementations, the memory device 500 may be coupled to the chip 1105 through hybrid bonding (e.g., metal to metal bonding, copper to copper bonding). For example, the back side of the chip 1105 may be coupled to the chip 501 of the memory device 500 through a hybrid bonding process. In one example, the plurality of pad interconnects 403a of the chip 501 may be coupled to and touch the plurality of back side interconnects of the chip 1105. In some implementations, the chip 1105 may be coupled to the memory device 500 through a plurality of solder interconnects (not shown).

The chip 1105 may include a central processing unit (CPU), a graphical processing unit (GPU) and/or neural processing unit (NPU), which allows the processing units to be located very close to the memory chips, resulting in faster processing and compute of data. A memory chip may include Dynamic Random Access Memory (DRAM). Different implementations may include a memory chip with different types of memory and/or different memory sizes. The stack of chips 1103 may include stacks of DRAM or any type and/or combination of memory types. The stack of chips 1103 may represent a high bandwidth memory (HBM).

The stack of chips 1103 may be electrically coupled to the chip 1101 through an electrical path that includes (i) a solder interconnect from the plurality of solder interconnects 1150, (ii) at least one interconnect from the plurality of interconnects 1141, (iii) a solder interconnect from the plurality of solder interconnects 1112 and/or (iv) a pillar interconnect from the plurality of pillar interconnects 1110.

In some implementations, the substrate 1104 may be optional. In such instances, the chip 1101 may be coupled to the substrate 1102 through the plurality of pillar interconnects 1110 and the plurality of solder interconnects 1112. The plurality of solder interconnects 1112 may be coupled to and touch the plurality of pillar interconnects 1110 and the plurality of interconnects 1121 of the substrate 1102. Moreover, when the substrate 1104 is optional, the stack of chips 1103 may be coupled to the substrate 1102 through the plurality of solder interconnects 1150, such that the plurality of solder interconnects 1150 are coupled to and touch the plurality of interconnects 1121 of the substrate 1102. When the substrate 1104 is optional, the stack of chips 1103 may be electrically coupled to the chip 1101 through an electrical path that includes (i) a solder interconnect from the plurality of solder interconnects 1150, (ii) at least one interconnect from the plurality of interconnects 1121, (iii) a solder interconnect from the plurality of solder interconnects 1112 and/or (iv) a pillar interconnect from the plurality of pillar interconnects 1110.

In some implementations, the chip 1101 may be a first chiplet based on a first technology node and the stack of chips 1103 may include at least one chiplet based on a second technology node, that is different from the first technology node. For example, the chip 1105, the chip 501, the chip 502, the chip 503 and/or the chip 504 may be chiplets based on one or more technology nodes that is/are different the technology node used to fabricate the chip 1101. In some implementations, the chip 1105 may be a first chiplet based on a first technology node and the chip 501 may be a second chiplet based on a second technology node, that is different from the first technology node. In some implementations, the chip 1105, 501, the chip 502, the chip 503, and/or the chip 504 are chiplets based on the same technology node.

In some implementations, the memory device is a high bandwidth memory (HBM). In some implementations, the chip 1101 is implemented as a System on Chip (SoC). In some implementations, a first chip from the memory device 500 is a first chiplet based on a first technology node, and a second chip from the memory device 500 is a second chiplet based on a second technology node, that is different from the first technology node. In some implementations, a first chip from the memory device 500 is a first chiplet based on a first technology node, and the chip 1105 is a second chiplet based on a second technology node, that is different from the first technology node. In some implementations, a first chip from the memory device 500 is a first chiplet based on a first technology node, and the chip 1101 is a second chiplet based on a second technology node, that is different from the first technology node. In some implementations, the chip 1105 is a first chiplet based on a first technology node, and the chip 1101 is a second chiplet based on a second technology node, that is different from the first technology node. The meaning of a technology node is further described below.

Although one stack of chips is shown, a package may include two or more stacks of chips. The stack of chips may be similar to each other. The stack of chips may have different number of chips. Similarly, two or more chips may be coupled to the substrate 1102 or the substrate 1104.

### Exemplary Sequence for Fabricating a Package Comprising a Stack of Chips

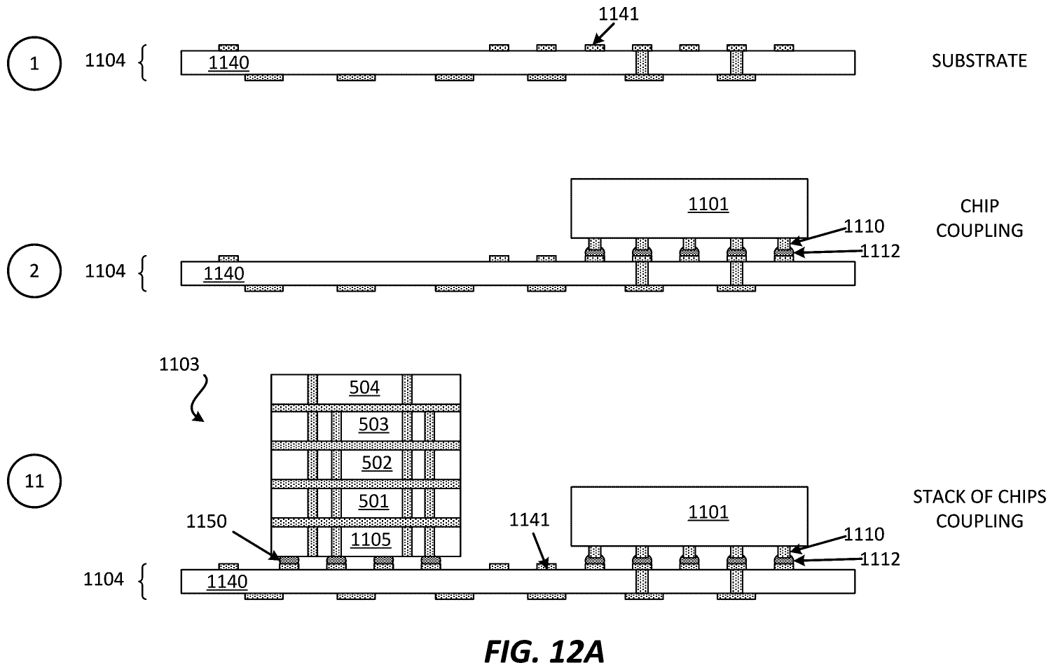

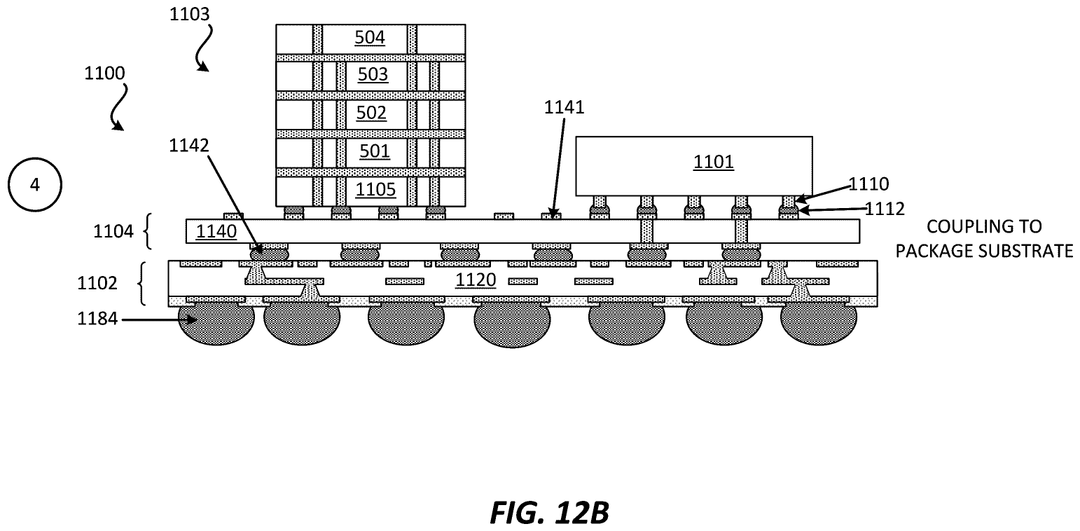

In some implementations, fabricating a package includes several processes. FIGS. 12A-12B illustrate an exemplary sequence for providing or fabricating a package. In some implementations, the sequence of FIGS. 12A-12B may be used to provide or fabricate the package 1100. However, the process of FIGS. 12A-12B may be used to fabricate any of the packages described in the disclosure.

It should be noted that the sequence of FIGS. 12A-12B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 12A, illustrates a state after a substrate 1104 is provided. The substrate 1104 includes at least one dielectric layer 1140 and a plurality of interconnects 1141. The substrate 1104 may be an interposer.

Stage 2 illustrates a state after the chip 1101 is coupled to the substrate 1104 through a plurality of pillar interconnects 1110 and a plurality of solder interconnects 1112. The plurality of solder interconnects 1112 may be coupled to the plurality of interconnects 1141 of the substrate 1104 through a solder reflow process.

Stage 3 illustrates a state after the stack of chips 1103 is coupled to the substrate 1104 through a plurality of solder interconnects 1150. The plurality of solder interconnects 1150 may be coupled to the plurality of interconnects 1141 of the substrate 1104 through a solder reflow process. The stack of chips 1103 is located laterally adjacent and/or near the chip 1101. The stack of chips 1103 may include a chip 1105 and the memory device 500. In some implementations, the stack of chips 1103 may be coupled to the substrate 1104.

Stage 4, as shown in FIG. 12B, illustrates a state after the substrate 1104 is coupled to the substrate 1102 through a plurality of solder interconnects 1142. The substrate 1102 may include at least one dielectric layer 1120 and a plurality of interconnects 1121. The plurality of solder interconnects 1142 may be coupled to the plurality of interconnects 1121 of the substrate 1102 through a solder reflow process.

### Exemplary Flow Diagram of a Method for Fabricating a Package Comprising a Stack of Chips

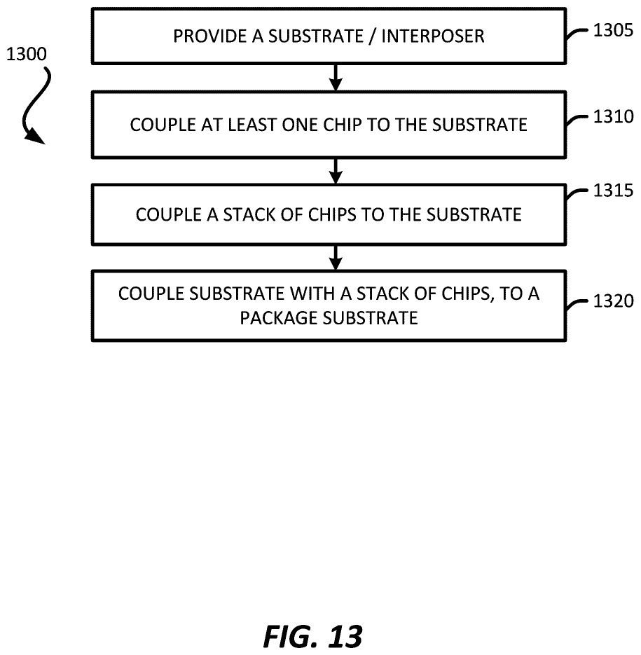

In some implementations, fabricating a package includes several processes. FIG. 13 illustrates an exemplary flow diagram of a method 1300 for providing or fabricating a package. In some implementations, the method 1300 of FIG. 13 may be used to provide or fabricate the package 1100 described in the disclosure. However, the method 1300 may be used to provide or fabricate any of the packages described in the disclosure.

It should be noted that the method 1300 of FIG. 13 may combine one or more processes in order to simplify and/or clarify the method for providing or fabricating a package. In some implementations, the order of the processes may be changed or modified.

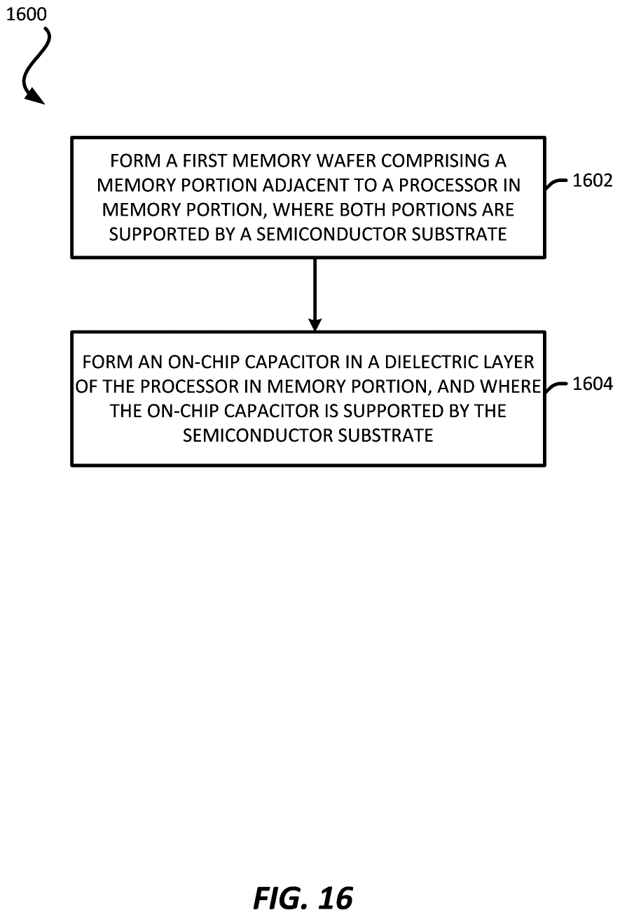

The method provides (at 1305) a substrate. Stage 1 of FIG. 16A, illustrates a state after a substrate 1104 is provided. The substrate 1104 includes at least one dielectric layer 1140 and a plurality of interconnects 1141. The substrate 1104 may be an interposer.

The method couples (at 1310) a chip to the substrate. Stage 2 of FIG. 12A, illustrates a state after the chip 1101 is coupled to the substrate 1104 through a plurality of pillar interconnects 1110 and a plurality of solder interconnects 1112. The plurality of solder interconnects 1112 may be coupled to the plurality of interconnects 1141 of the substrate 1104 through a solder reflow process.

The method couples (at 1315) a stack of chips to the substrate. Stage 3 of FIG. 12A, illustrates a state after the stack of chips 1103 is coupled to the substrate 1104 through a plurality of solder interconnects 1150. The plurality of solder interconnects 1150 may be coupled to the plurality of interconnects 1141 of the substrate 1104 through a solder reflow process. The stack of chips 1103 is located laterally adjacent and/or near the chip 1101. The stack of chips 1103 may include a chip 1105 and the memory device 500. In some implementations, the stack of chips 1103 may be coupled to the substrate 1104.

The method couples (at 1320) the substrate with a stack of chips, to a package substrate. Stage 4 of FIG. 12B, illustrates a state after the substrate 1104 is coupled to the substrate 1102 through a plurality of solder interconnects 1142. The substrate 1102 may include at least one dielectric layer 1120 and a plurality of interconnects 1121. The plurality of solder interconnects 1142 may be coupled to the plurality of interconnects 1121 of the substrate 1102 through a solder reflow process.

### Exemplary Sequence for Fabricating a Capacitor in a Chip

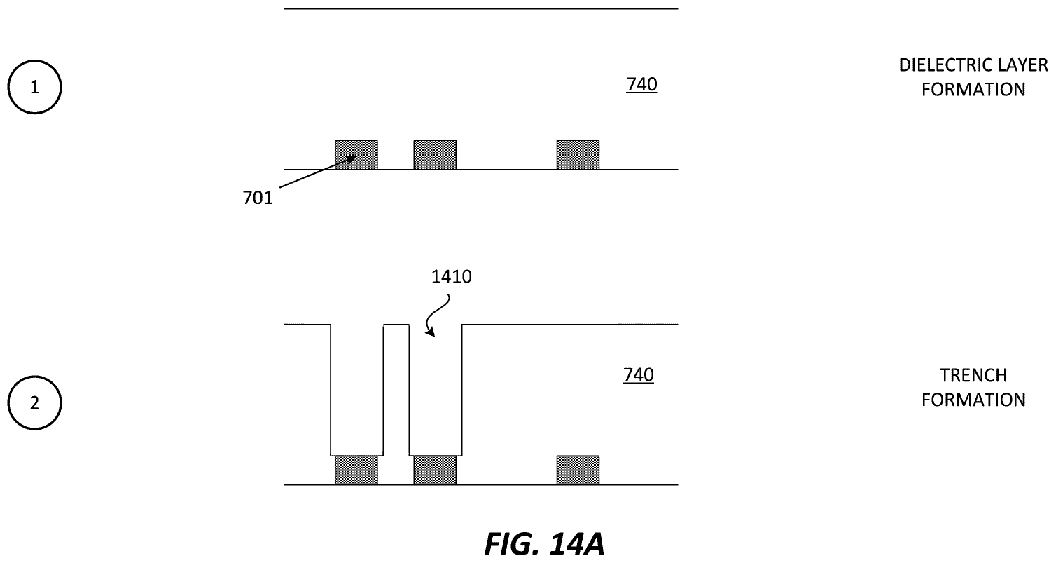

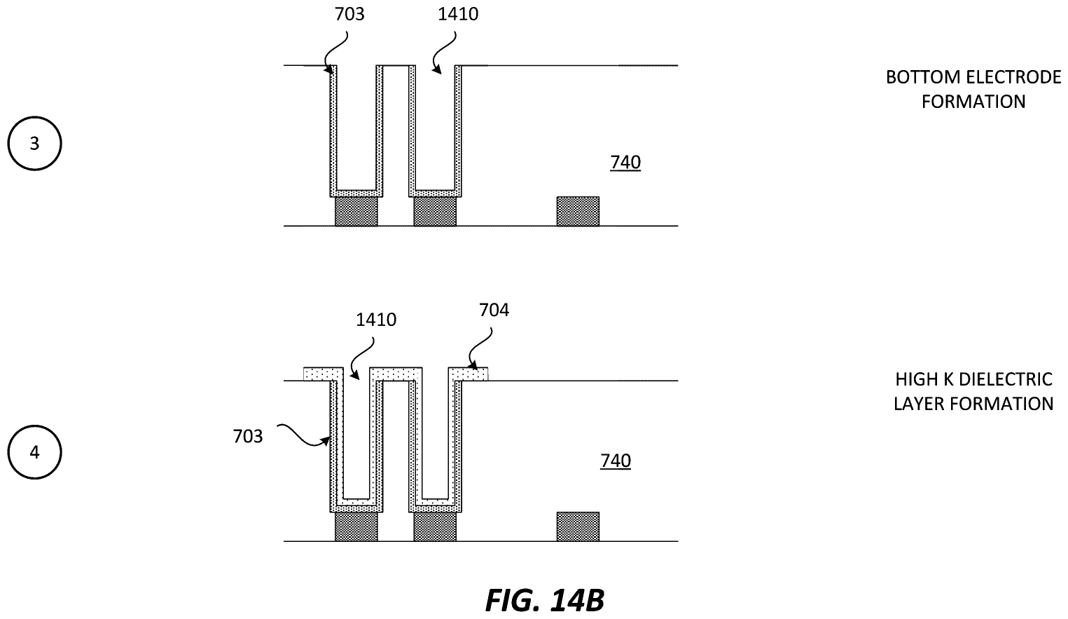

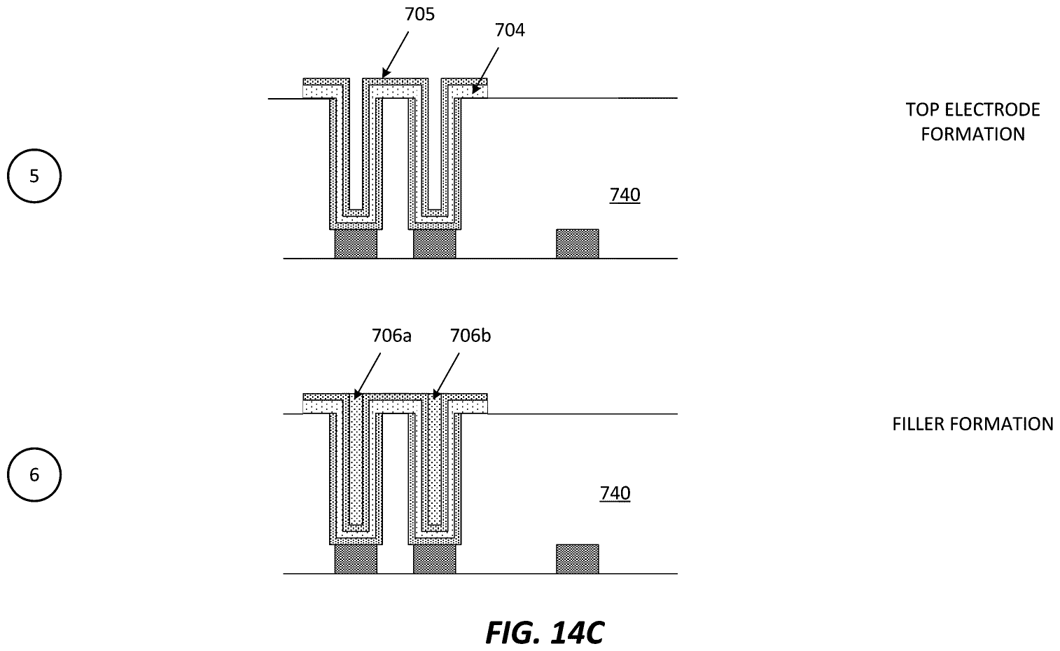

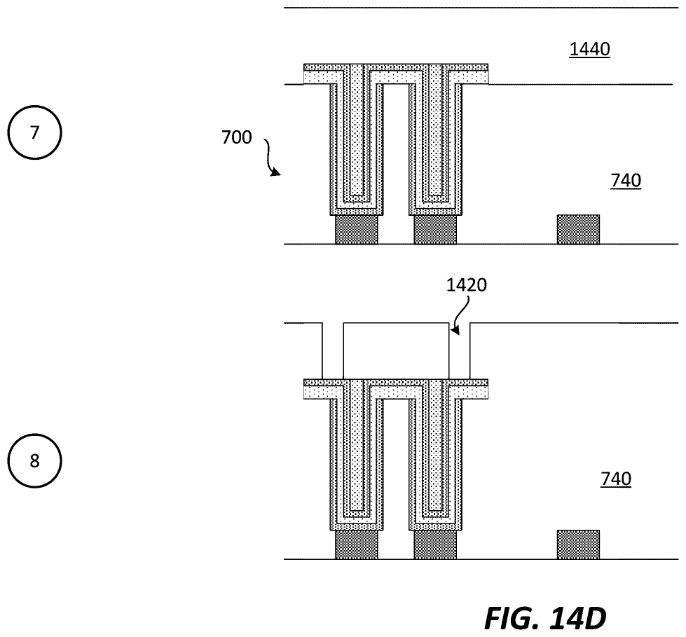

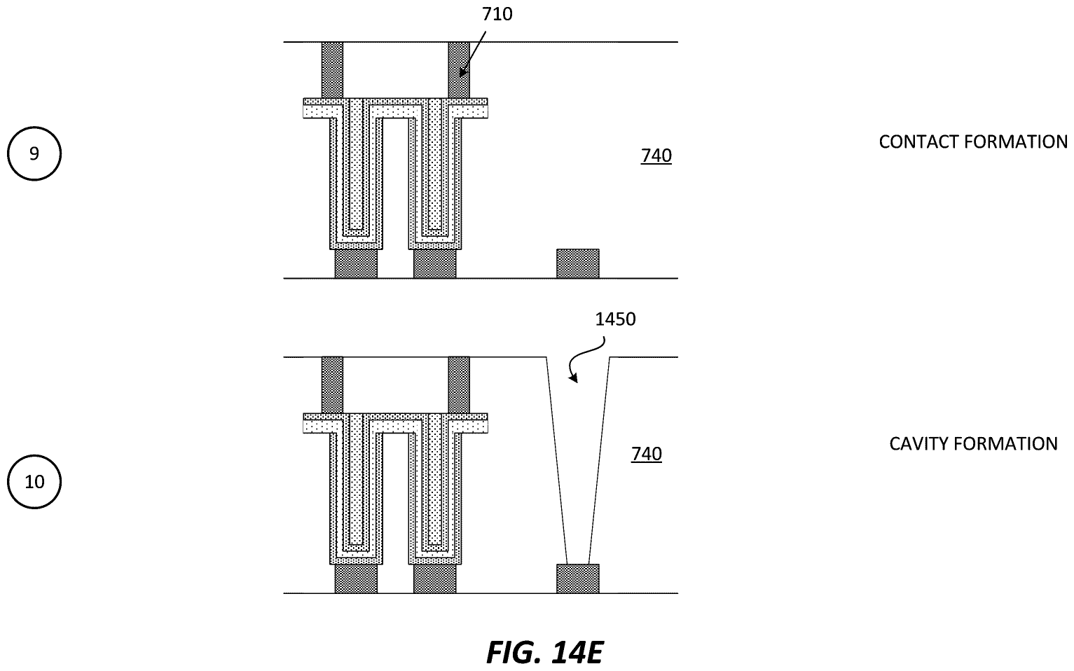

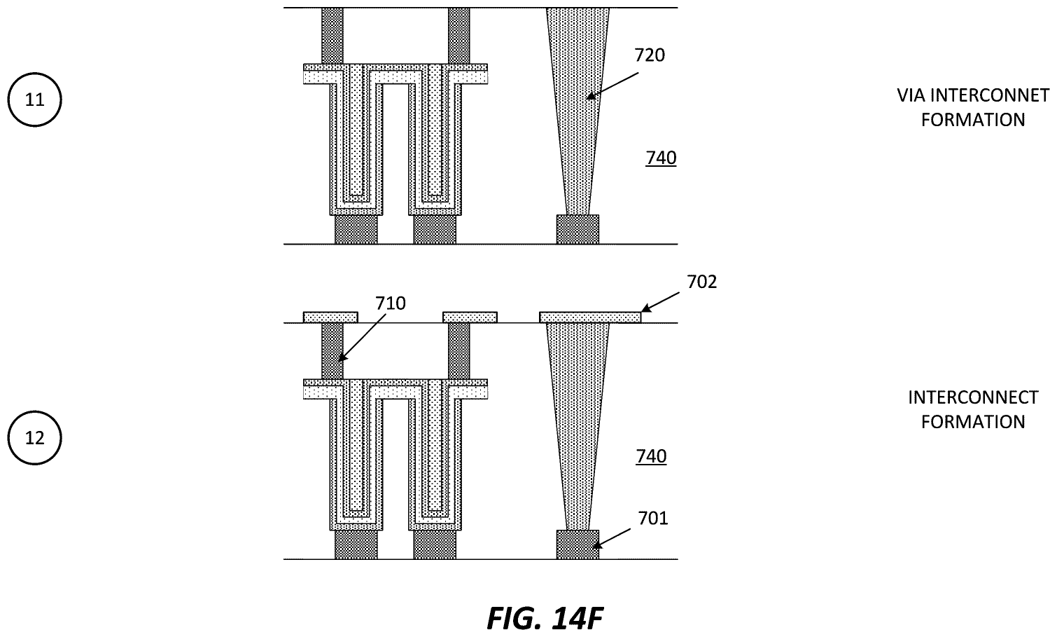

In some implementations, fabricating a capacitor includes several processes. FIGS. 14A-14F illustrate an exemplary sequence for providing or fabricating a capacitor. In some implementations, the sequence of FIGS. 14A-14F may be used to provide or fabricate the capacitor from the plurality of capacitors 700. However, the process of FIGS. 14A-14F may be used to fabricate any of the capacitors described in the disclosure.

It should be noted that the sequence of FIGS. 14A-14F may combine one or more stages in order to simplify and/or clarify the sequence for providing or fabricating a capacitor. In some implementations, the order of the processes may be changed or modified. In some implementations, one or more of processes may be replaced or substituted without departing from the scope of the disclosure.

Stage 1, as shown in FIG. 14A, illustrates a state after a dielectric layer 740 is formed. The dielectric layer 740 may be a dielectric layer of a chip or a wafer. The dielectric layer 740 is formed in and/or above the processor in memory portion of the chip or the wafer. The dielectric layer 740 may be formed through a lamination process or a deposition process. The dielectric layer 740 may be formed over the plurality of interconnects 701. The plurality of interconnects 701 may correspond to a metal layer of a chip or a wafer. The dielectric layer 740 may correspond to the at least one dielectric layer 440 of the chip 400.

Stage 2 illustrates a state after a plurality of trenches 1410 in the dielectric layer 740. A laser process (e.g., laser ablation) may be formed in the dielectric layer 740. The plurality of trenches 1410 may be a plurality of cavities with high aspect ratios (e.g., high height to width ratios). Stage 3, as shown in FIG. 14B, illustrates a state after a first electrode 703 is formed. The first electrode 703 may be formed in the plurality of trenches 1410. In some implementations, the first electrode 703 may include heavily doped polysilicon or tungsten (W). A plating process may be used to form the first electrode 703.

Stage 4 illustrates a state after a capacitor dielectric layer 704 is formed over the first electrode 703. The capacitor dielectric layer 704 may be formed in the plurality of trenches 1410. A lamination process and/or a deposition process may be used to form the capacitor dielectric layer 704. In some implementations, the capacitor dielectric layer 704 may be a high K dielectric layer, such as zirconium dioxide (ZrO₂) and oxide-nitride-oxide (ONO).

Stage 5, as shown in FIG. 14C, illustrates a state after a second electrode 705 is formed. The second electrode 705 may be formed in the plurality of trenches 1410. In some implementations, the second electrode 705 may include titanium nitride (TiN). The second electrode 705 may be formed on the capacitor dielectric layer 704. A plating process may be used to form the second electrode 705.

Stage 6 illustrates a state after a filler 706 is formed. The filler 706 may include a heavily doped polysilicon or tungsten (W) located between different portions of the second electrode 705. The filler 706 may be located in the plurality of trenches 1410. A plating process may be used to form the filler 706.

Stage 7, as shown in FIG. 14D, illustrates a state after a dielectric layer 1440 is formed over the plurality of capacitors 700 and the dielectric layer 740. The dielectric layer 1440 may be the same or similar to the dielectric layer 740. A lamination process or a deposition process may be used to form the dielectric layer 1440. The dielectric layer 1440 may be considered part of the dielectric layer 740.

Stage 8 illustrates a state after a plurality of cavities 1420 are formed in the dielectric layer 740. A laser process or an etching process may be used to form the plurality of cavities 1420 in the dielectric layer 740.

Stage 9, as shown in FIG. 14E, illustrates a state after a plurality of interconnects 710 are formed. A plating process may be used to form the plurality of interconnects 710 that are coupled to the second electrode 705.

Stage 10 illustrates a state after a plurality of cavities 1450 are formed in the dielectric layer 740. A laser process or an etching process may be used to form the plurality of cavities 1450 in the dielectric layer 740.

Stage 11, as shown in FIG. 14F, illustrates a state after a plurality of via interconnects 720 are formed. A plating process may be used to form the plurality of via interconnects 720. The plurality of via interconnects 720 may be coupled to the plurality of interconnects 701.

Stage 12 illustrates a state after a plurality of interconnects 702 are formed and coupled to the plurality of via interconnects 720 and the plurality of interconnects 710. A plating process may be used to form the plurality of interconnects 702.

### Exemplary Flow Diagram of a Method for Fabricating a Capacitor in a Chip

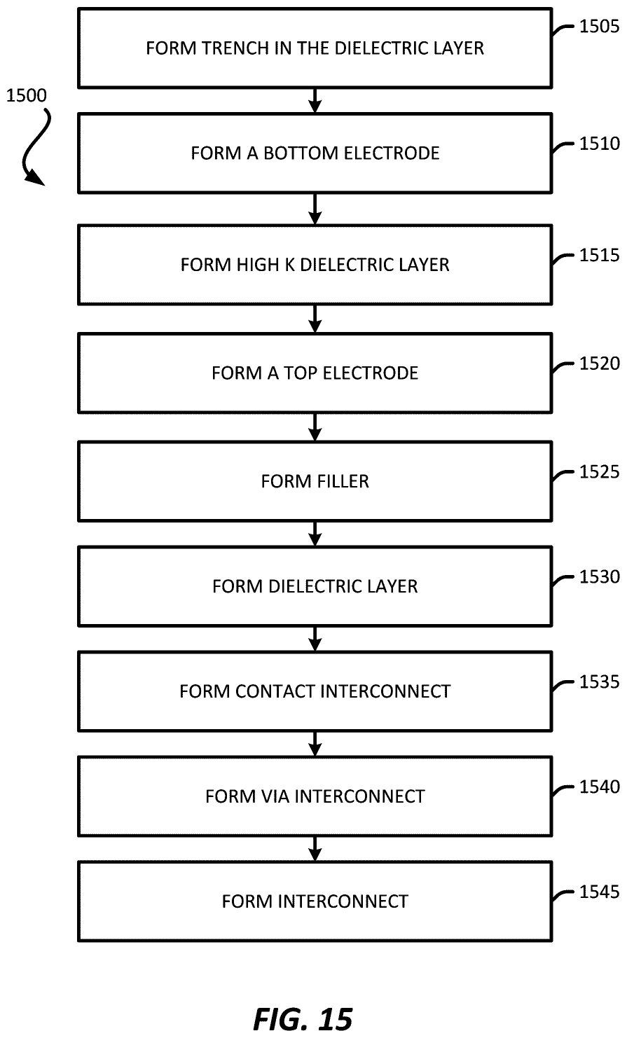

In some implementations, fabricating a chip includes several processes. FIG. 15 illustrates an exemplary flow diagram of a method 1500 for providing or fabricating a capacitor in a chip. In some implementations, the method 1500 of FIG. 15 may be used to provide or fabricate the capacitor from the plurality of capacitors 700 described in the disclosure. However, the method 1500 may be used to provide or fabricate any of the capacitors described in the disclosure.

It should be noted that the method 1500 of FIG. 15 may combine one or more processes in order to simplify and/or clarify the method for providing or fabricating a capacitor in a chip. In some implementations, the order of the processes may be changed or modified.

The method forms (at 1505) a plurality of trenches in a dielectric layer. Stage 1 of FIG. 14A, illustrates a state after a dielectric layer 740 is formed. The dielectric layer 740 may be a dielectric layer of a chip or a wafer. The dielectric layer 740 is formed in and/or above the processor in memory portion of the chip or the wafer. The dielectric layer 740 may be formed through a lamination process or a deposition process. The dielectric layer 740 may be formed over the plurality of interconnects 701. The plurality of interconnects 701 may correspond to a metal layer of a chip or a wafer. The dielectric layer 740 may correspond to the at least one dielectric layer 440 of the chip 400.

Stage 2 of FIG. 14A, illustrates a state after a plurality of trenches 1410 are formed in the dielectric layer 740. A laser process (e.g., laser ablation) may be formed in the dielectric layer 740. The plurality of trenches 1410 may be a plurality of cavities with high aspect ratios (e.g., high height to width ratios).

The method forms (at 1510) a bottom electrode in the plurality of trenches. Stage 3 of FIG. 14B, illustrates a state after a first electrode 703 is formed. The first electrode 703 may be formed in the plurality of trenches 1410. In some implementations, the first electrode 703 may include heavily doped polysilicon or tungsten (W). A plating process may be used to form the first electrode 703.

The method forms (at 1515) a capacitor dielectric layer in the plurality of trenches. Stage 4 of FIG. 14B, illustrates a state after a capacitor dielectric layer 704 is formed over the first electrode 703. The capacitor dielectric layer 704 may be formed in the plurality of trenches 1410. A lamination process and/or a deposition process may be used to form the capacitor dielectric layer 704. In some implementations, the capacitor dielectric layer 704 may be a high K dielectric layer, such as zirconium dioxide (ZrO₂) and oxide-nitride-oxide (ONO).

The method forms (at 1520) a top electrode in the plurality of trenches. Stage 5 of FIG. 14C, illustrates a state after a second electrode 705 is formed. The second electrode 705 may be formed in the plurality of trenches 1410. In some implementations, the second electrode 705 may include titanium nitride (TiN). The second electrode 705 may be formed on the capacitor dielectric layer 704. A plating process may be used to form the second electrode 705.

The method forms (at 1525) a filler in the plurality of trenches. Stage 6 of FIG. 14C, illustrates a state after a filler 706 is formed. The filler 706 may include a heavily doped polysilicon or tungsten (W) located between different portions of the second electrode 705. The filler 706 may be located in the plurality of trenches 1410. A plating process may be used to form the filler 706.

The method forms (at 1530) a dielectric layer over the plurality of capacitors. Stage 7 of FIG. 14D, illustrates a state after a dielectric layer 1440 is formed over the plurality of capacitors 700 and the dielectric layer 740. The dielectric layer 1440 may be the same or similar to the dielectric layer 740. A lamination process or a deposition process may be used to form the dielectric layer 1440. The dielectric layer 1440 may be considered part of the dielectric layer 740.

The method forms (at 1535) a plurality of contact interconnects. Stage 8 of FIG. 14D, illustrates a state after a plurality of cavities 1420 are formed in the dielectric layer 740. A laser process or an etching process may be used to form the plurality of cavities 1420 in the dielectric layer 740. Stage 9 of FIG. 14E, illustrates a state after a plurality of interconnects 710 are formed. A plating process may be used to form the plurality of interconnects 710 that are coupled to the second electrode 705.

The method forms (at 1540) a plurality of via interconnects. Stage 10 of FIG. 14E, illustrates a state after a plurality of cavities 1450 are formed in the dielectric layer 740. A laser process or an etching process may be used to form the plurality of cavities 1450 in the dielectric layer 740. Stage 11 of FIG. 14F, illustrates a state after a plurality of via interconnects 720 are formed. A plating process may be used to form the plurality of via interconnects 720. The plurality of via interconnects 720 may be coupled to the plurality of interconnects 701.

The method forms (at 1545) illustrates a state after a plurality of interconnects are formed and coupled to the plurality of via interconnects and the plurality of contact interconnects. Stage 12 of FIG. 14F, illustrates a state after a plurality of interconnects 702 is formed and coupled to the plurality of via interconnects 720 and the plurality of interconnects 710. A plating process may be used to form the plurality of interconnects 702.

### Exemplary Flow Diagram of a Method for Fabricating a Chip With a Memory Portion and a Processor in Memory Portion

In some implementations, fabricating a chip includes several processes. FIG. 16 illustrates an exemplary flow diagram of a method 1600 for providing or fabricating a chip. In some implementations, the method 1600 of FIG. 16 may be used to provide or fabricate the chip 1600 described in the disclosure. However, the method 1600 may be used to provide or fabricate any of the chips described in the disclosure.

It should be noted that the method 1600 of FIG. 16 may combine one or more processes in order to simplify and/or clarify the method for providing or fabricating a package. In some implementations, the order of the processes may be changed or modified.

The method provides (at 1602) a wafer comprising a memory portion and a processor in memory portion. The memory portion is adjacent to the processor in memory portion. Forming the memory portion and the processor in memory portion may include forming an active region (e.g., comprising transistors) on a semiconductor substrate, such as a silicon substrate.

The method forms (at 1604) a plurality of capacitors. The plurality of capacitors may be formed in a dielectric layer located over the active region of the processor in memory portion. Different implementations, may use different capacitors with different designs and/or materials. The plurality of capacitors may be considered part of the processor in memory portion of the chip and/or the wafer.

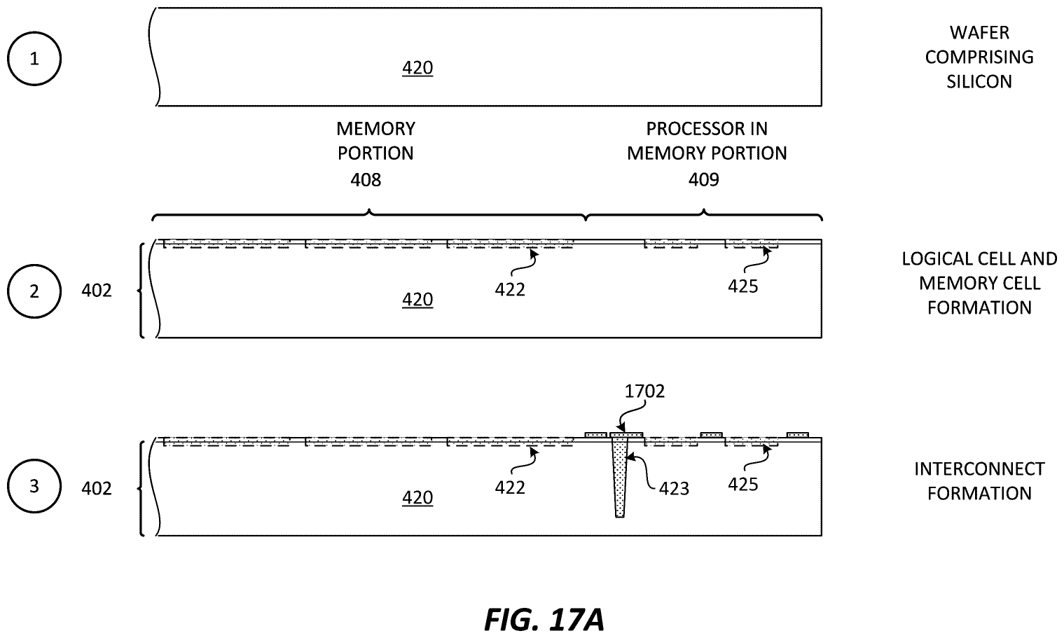

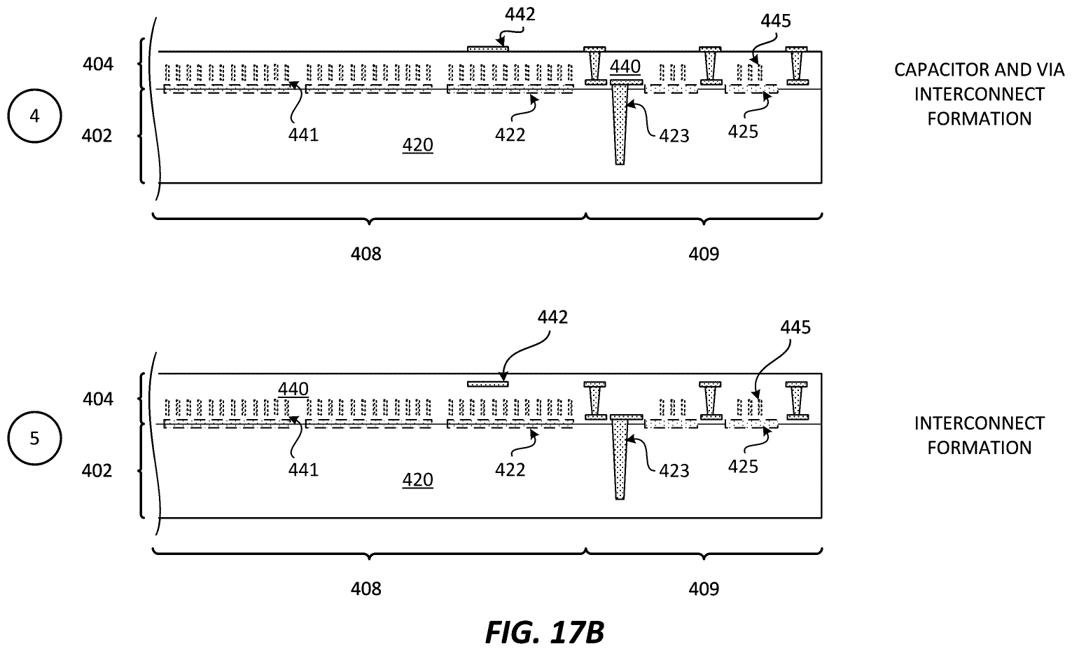

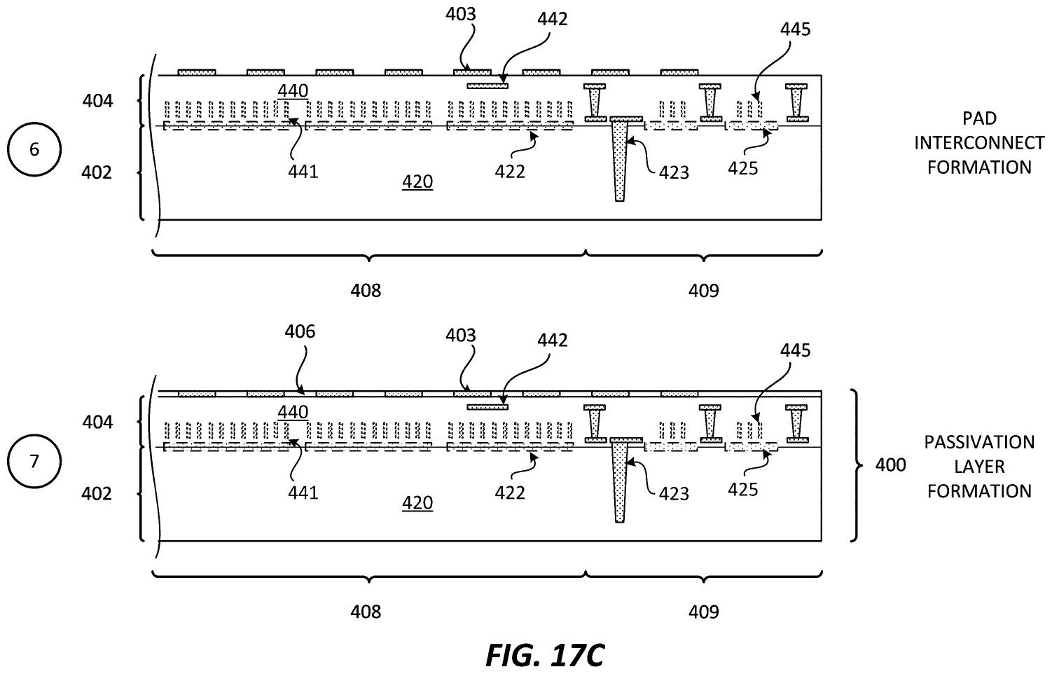

The wafer may be singulated to form a plurality of chips. FIGS. 17A-17C illustrate a sequence of a process for fabricating a chip that includes a memory portion and a processor in memory portion.

### Exemplary Sequence for Fabricating a Chip Comprising a Capacitor in the Processor in Memory Portion

In some implementations, fabricating a chip includes several processes. FIGS. 17A-17C illustrate an exemplary sequence for providing or fabricating a chip with a capacitor in the processor in memory portion. In some implementations, the sequence of FIGS. 17A-17C may be used to provide or fabricate the chip 400 with a plurality of capacitors 445. However, the process of FIGS. 17A-17C may be used to fabricate any of the chips described in the disclosure.

It should be noted that the sequence of FIGS. 17A-17C may combine one or more stages in order to simplify and/or clarify the sequence for providing or fabricating a chip comprising a capacitor. In some implementations, the order of the processes may be changed or modified. In some implementations, one or more of processes may be replaced or substituted without departing from the scope of the disclosure.

Stage 1, as shown in FIG. 17A, illustrates a state after a wafer is provided. The wafer includes a die substrate 420. The die substrate 420 may include silicon.

Stage 2 illustrates a state after an active region 422 and an active region 425 are formed. The active region 422 may be part of the memory portion 408. The active region 425 may be part of the processor in memory portion 409. In some implementations, a front end of line (FEOL) process may be used to fabricate the active region 422 and the active region 425.

Stage 3 illustrates a state after a plurality of via interconnects 423 and a plurality of interconnects 1702 are formed. In some implementations, forming the plurality of via interconnects 423 may include forming a plurality of cavities in the die substrate 420. A laser process may be used to form the plurality of cavities in the die substrate 420. A plating process may be used to form the plurality of via interconnects 423 and the plurality of interconnects 1702.

Stage 4 of FIG. 17B, illustrates a state after a plurality of capacitors 441 are formed in the memory portion 408, and after a plurality of capacitors 445 are formed in the processor in memory portion 409. A plurality of via interconnects may also be formed in the processor in memory portion 409. FIGS. 14A-14F illustrate an example of a process for fabricating a capacitor and a plurality of via interconnects.

Stage 5 illustrates a state after a plurality of die interconnects 442 and at least one dielectric layer are formed. A lamination process may be used to form the dielectric layer and a plating process may be used to form the plurality of die interconnects 442.

Stage 6, as shown in FIG. 17C, illustrates a state after a plurality of pad interconnects 403 are formed and coupled to the plurality of die interconnects 442. A plating process may be used to form the plurality of pad interconnects 403.

Stage 7 illustrates a state after a passivation layer 406 is formed and coupled to the at least one dielectric layer 440. A lamination process and/or a deposition process may be used to form the passivation layer 406.

In some implementations, the wafer may be singulated to form a chip 400 that includes a capacitor in the processor in memory portion 409.

### Exemplary Flow Diagram of a Method for Fabricating a Chip With a Memory Portion and a Processor in Memory Portion

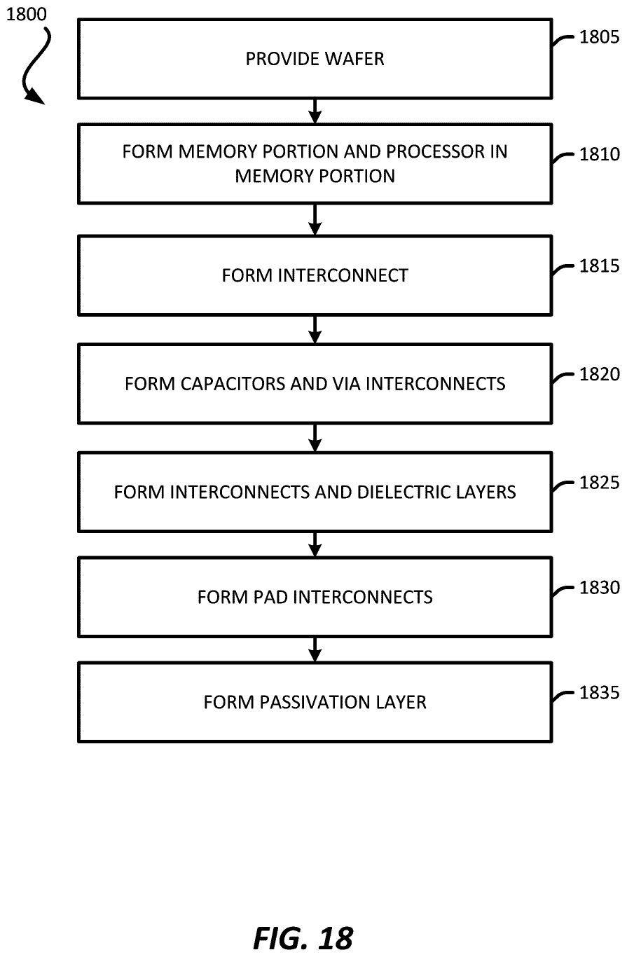

In some implementations, fabricating a chip includes several processes. FIG. 18 illustrates an exemplary flow diagram of a method 1800 for providing or fabricating a chip. In some implementations, the method 1800 of FIG. 18 may be used to provide or fabricate the chip 1800 described in the disclosure. However, the method 1800 may be used to provide or fabricate any of the chips described in the disclosure.

It should be noted that the method 1800 of FIG. 18 may combine one or more processes in order to simplify and/or clarify the method for providing or fabricating a package. In some implementations, the order of the processes may be changed or modified.

The method forms (at 1805) a wafer. Stage 1 of FIG. 17A, illustrates a state after a wafer is provided. The wafer includes a die substrate 420. The die substrate 420 may include silicon.

The method forms (at 1810) a memory portion and a processor in memory portion. Stage 2 of FIG. 17A, illustrates a state after an active region 422 and an active region 425 are formed. The active region 422 may be part of the memory portion 408. The active region 425 may be part of the processor in memory portion 409. In some implementations, a front end of line (FEOL) process may be used to fabricate the active region 422 and the active region 425.

The method forms (at 1815) a plurality of interconnects and/or a plurality of via interconnects. Stage 3 of FIG. 17B, illustrates after state a plurality of via interconnects 423 and a plurality of interconnects 1702 are formed. In some implementations, forming the plurality of via interconnects 423 may include forming a plurality of cavities in the die substrate 420. A laser process may be used to form the plurality of cavities in the die substrate 420. A plating process may be used to form the plurality of via interconnects 423 and the plurality of interconnects 1702.

The method forms (at 1820) a plurality of capacitors and a plurality of via interconnects. Stage 4 of FIG. 17B, illustrates a state after a plurality of capacitors 441 are formed in the memory portion 408, and after a plurality of capacitors 445 are formed in the processor in memory portion 409. A plurality of via interconnects may also be formed in the processor in memory portion 409. FIGS. 14A-14F illustrate an example of a process for fabricating a capacitor and a plurality of via interconnects.

The method forms (at 1825) a plurality of interconnects and at least one dielectric layer. Stage 5 of FIG. 17B, illustrates a state after a plurality of die interconnects 442 and at least one dielectric layer are formed. A lamination process may be used to form the dielectric layer and a plating process may be used to form the plurality of die interconnects 442.

The method forms (at 1830) a plurality of pad interconnects. Stage 6 of FIG. 17C, illustrates a state after a plurality of pad interconnects 403 are formed and coupled to the plurality of die interconnects 442. A plating process may be used to form the plurality of pad interconnects 403.

The method forms (at 1835) a passivation layer. Stage 7 of FIG. 17C, illustrates a state after a passivation layer 406 is formed and coupled to the at least one dielectric layer 440. A lamination process and/or a deposition process may be used to form the passivation layer 406.

In some implementations, the wafer may be singulated to form a chip 400 that includes a capacitor in the processor in memory portion 409.

### Exemplary Semiconductor Chip

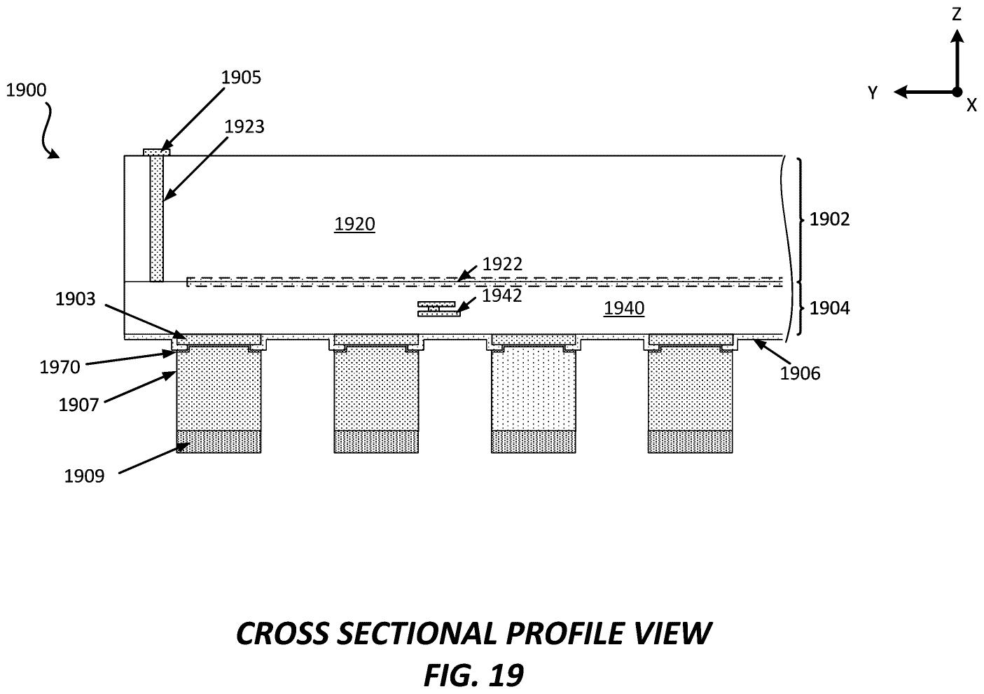

FIG. 19 illustrates a cross sectional profile view of a chip 1900. The chip 1900 may represent the chip 1101 and/or any other chip in the disclosure. The chip 1900 may be a semiconductor chip. The chip 1900 may be an integrated circuit (IC) chip. The chip 1900 includes a die substrate portion 1902, a die interconnection portion 1904, a plurality of pad interconnects 1903, and/or a passivation layer 1906. The chip 1900 may further include a plurality of under bump metallization interconnects 1970, a plurality of pillar interconnects 1907 and/or a plurality of solder interconnects 1909. The chip 1900 may be fabricated using a process that includes a silicon based fabrication process.

The die substrate portion 1902 includes a die substrate 1920 and an active region 1922. The die substrate 1920 may include silicon (Si). The active region 1922 may be formed in the die substrate 1920 and/or a surface of the die substrate 1920. The active region 1922 may include a plurality of logic cells and/or a plurality of transistors. One or more transistors may define a logic cell. The plurality of logic cells may include functioning logic cells when the integrated device is in operation. The plurality of transistors may include functioning transistors. Different implementations may use different types of transistors, such as a field effect transistor (FET), planar FET, finFET, and a gate all around FET. In some implementations, a front end of line (FEOL) process may be used to fabricate the plurality of cells and/or transistors in and/or over the die substrate 1920. In some implementations, the die substrate portion 1902 may include a plurality of through substrate vias 1923 that extend through the die substrate 1920. A back side metallization portion 1905 may be coupled to the die substrate 1920. The back side metallization portion 1905 may include a plurality of back side metallization interconnects that are coupled to the through substrate vias 1923 that extend through the die substrate 1920.

The die interconnection portion 1904 is coupled to the die substrate portion 1902. For example, the die interconnection portion 1904 is coupled to the die substrate 1920. The die interconnection portion 1904 includes at least one dielectric layer 1940 and a plurality of die interconnects 1942. The die interconnection portion 1904 may be configured to be electrically coupled to the active region 1922. For example, the plurality of die interconnects 1942 may be configured to be electrically coupled to the active region 1922. Thus, the plurality of die interconnects 1942 may be configured to be electrically coupled to the plurality of logic cells and/or plurality of transistors. In some implementations, a back end of line (BEOL) process may be used to fabricate the die interconnection portion 1904. The die interconnection portion 1904 may be a BEOL die interconnection portion. The plurality of die interconnects 1942 may include copper (Cu). In some implementations, the at least one dielectric layer 1940 may include silicon dioxide (SiO₂). The die interconnection portion 1904 may be formed over the die substrate portion 1902. The plurality of pad interconnects 1903 are coupled to the die interconnection portion 1904. The plurality of pad interconnects 1903 may be coupled to the plurality of die interconnects 1942.

The passivation layer 1906 is coupled to the die interconnection portion 1904. The passivation layer 1906 may be formed and coupled to a surface of the die interconnection portion 1904. The passivation layer 1906 may be coupled to and touch the at least one dielectric layer 1940. The passivation layer 1906 may be formed and coupled to part of the plurality of pad interconnects 1903. In some implementations, the passivation layer 1906 may include silicon nitride (SiN). However, different implementations may use different materials for the passivation layer 1906. The passivation layer 1906 may include a different material from the at least one dielectric layer 1940. The plurality of under bump metallization interconnects 1970 may be coupled to the plurality of pad interconnects 1903. The plurality of pillar interconnects 1907 may be coupled to the plurality of pad interconnects 1903 through the plurality of under bump metallization interconnects 1970. The plurality of solder interconnects 1909 may be coupled to the plurality of pillar interconnects 1907. The plurality of under bump metallization interconnects 1970, the plurality of pillar interconnects 1907 and/or the plurality of solder interconnects 1909 may be considered part of the chip 1900. In some implementations, the plurality of pillar interconnects 1907 and/or the plurality of under bump metallization interconnects 1970 may be optional. In such instances, the plurality of solder interconnects 1909 may be coupled to the plurality of pad interconnects 1903.

A chip can be a semiconductor chip. A chip can be an integrated circuit (IC) chip. A chip can include a plurality of transistors configured to perform logic operations and/or other functionalities. A chip can include capacitors and/or resistors. A chip can include a semiconductor substrate (e.g., silicon substrate) and interconnects. A chip can include a die (e.g., semiconductor bare die). The die can include a plurality of transistors configured to perform logic operations and/or other functionalities.

A chip may be a type of integrated circuit (IC) device and/or a type of an integrated device. A chip may include a power management integrated circuit (PMIC). A chip may include an application processor. A chip may include a modem. A chip may include a radio frequency (RF) device, a passive device, a filter, a capacitor, an inductor, an antenna, a transmitter, a receiver, a gallium arsenide (GaAs) based chip, a surface acoustic wave (SAW) filter, a bulk acoustic wave (BAW) filter, a light emitting diode (LED) integrated device, a silicon (Si) based chip, a silicon carbide (SiC) based chip, a memory, power management processor, and/or combinations thereof. A chip may include at least one electronic circuit (e.g., first electronic circuit, second electronic circuit, etc.). A chip may include an input/output (I/O) hub. A chip may be an example of an electrical component and/or electrical device.

In some implementations, a chip can be a chiplet. A chiplet may be fabricated using a process that provides better yields compared to other processes used to fabricate other types of chips and/or dies, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one or more integrated devices). As mentioned above, using several chiplets that perform several functions may reduce the overall cost of a package relative to using a single chip to perform all of the functions of a package. In some implementations, one of more of chiplets (e.g., 105) described in the disclosure may be fabricated using the same technology node or two or more different technology nodes. For example, a chip may be fabricated using a first technology node, and a chiplet may be fabricated using a second technology node that is not as advanced as the first technology node. In such an example, the chip may include components (e.g., interconnects, transistors) that have a first minimum size, and the chiplet may include components (e.g., interconnects, transistors) that have a second minimum size, where the second minimum size is greater than the first minimum size. In some implementations, a first chip and a second chip of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate a chiplet and/or a die. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the chip is locked into one technology node. To optimize the cost of a package, some of the functions can be implemented in different chiplets, where different integrated devices and/or chiplets may be fabricated using different technology nodes to reduce overall costs. For example, functions that require the use of the most advanced technology node may be implemented in a chip, and functions that can be implemented using a less advanced technology node can be implemented in another chip and/or one or more chiplets. One example, would be a chip, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single chip to perform all the functions of the package.

Another advantage of splitting the functions into several chips, dies and/or chiplets, is that it allows improvements in the performance of the package without having to redesign every single chip and/or chiplet. For example, if a configuration of a package uses a first chip and a first chiplet, it may be possible to improve the performance of the package by changing the design of the first chip, while keeping the design of the first chiplet the same. Thus, the first chiplet could be reused with the improved and/or different configured first chip. This saves cost by not having to redesign the first chiplet, when packages with improved chips are fabricated.

The package may be implemented in a radio frequency (RF) package. The RF package may be a radio frequency front end (RFFE) package. A package may be configured to provide Wireless Fidelity (WiFi) communication and/or cellular communication (e.g., 2G, 3G, 4G, 5G, 6G). The packages may be configured to support Global System for Mobile (GSM) Communications, Universal Mobile Telecommunications System (UMTS), and/or Long-Term Evolution (LTE). The packages may be configured to transmit and receive signals having different frequencies and/or communication protocols.

### Exemplary Electronic Devices

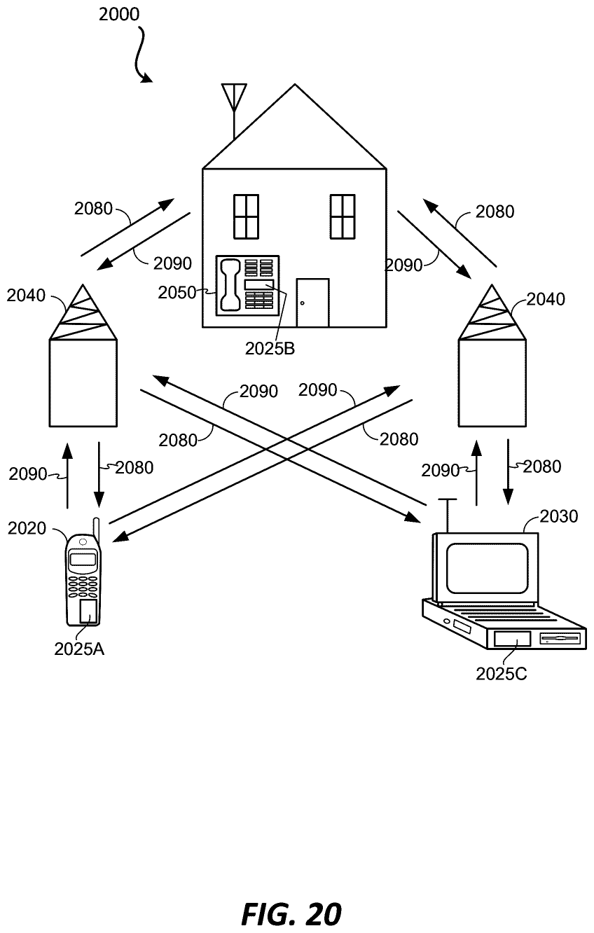

FIG. 20 is a block diagram showing an exemplary wireless communications system 2000 in which a configuration of the disclosure may be advantageously employed. For purposes of illustration, FIG. 20 shows three remote units 2020, 2030, and 2050, and two base stations 2040. It will be recognized that wireless communications systems may have many more remote units and base stations. Remote units 2020, 2030, and 2050 include integrated circuit (IC) devices 2025A, 2025C, and 2025B that include the disclosed memory cell array micro-structures in three-dimensional (3D) stacked DRAM for improved yield. It will be recognized that other devices may also include the disclosed the memory cell array micro-structures in 3D stacked DRAM for improved yield, such as the base stations, switching devices, and network equipment. FIG. 20 shows forward link signals 2080 from the base stations 2040 to the remote units 2020, 2030, and 2050, and reverse link signals 2090 from the remote units 2020, 2030, and 2050 to the base stations 2040.

In FIG. 20, remote unit 2020 is shown as a mobile telephone, remote unit 2030 is shown as a portable computer, and remote unit 2050 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 20 illustrates remote units according to aspects of the present disclosure, the disclosure is not limited to these exemplary illustrated units. Aspects of the present disclosure may be suitably employed in many devices, which include the disclosed the memory cell array micro-structures in 3D stacked DRAM for improved yield.

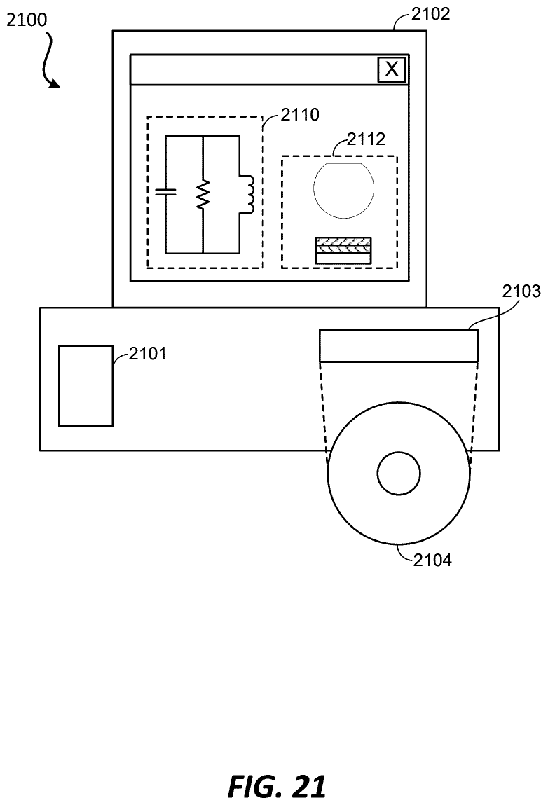

FIG. 21 is a block diagram illustrating a design workstation used for circuit, layout, and logic design of a semiconductor component, such as the vertical bank redundancy in three-dimensional (3D) stacked dynamic random-access memory (DRAM) for improved yield disclosed above. A design workstation 2100 includes a hard disk 2101 containing operating system software, support files, and design software such as Cadence or OrCAD. The design workstation 2100 also includes a display 2102 to facilitate design of a circuit 2110 or an integrated circuit (IC) component 2112, such as the memory cell array micro-structures in 3D stacked DRAM for improved yield. A storage medium 2104 is provided for tangibly storing the design of the circuit 2110 or the IC component 2112 (e.g., the memory cell array micro-structures). The design of the circuit 2110 or the IC component 2112 may be stored on the storage medium 2104 in a file format such as GDSII or GERBER. The storage medium 2104 may be a CD-ROM, DVD, hard disk, flash memory, or other appropriate device. Furthermore, the design workstation 2100 includes a drive apparatus 2103 for accepting input from or writing output to the storage medium 2104.

Data recorded on the storage medium 2104 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 2104 facilitates the design of the circuit 2110 or the IC component 2112 by decreasing the number of processes for designing semiconductor wafers.

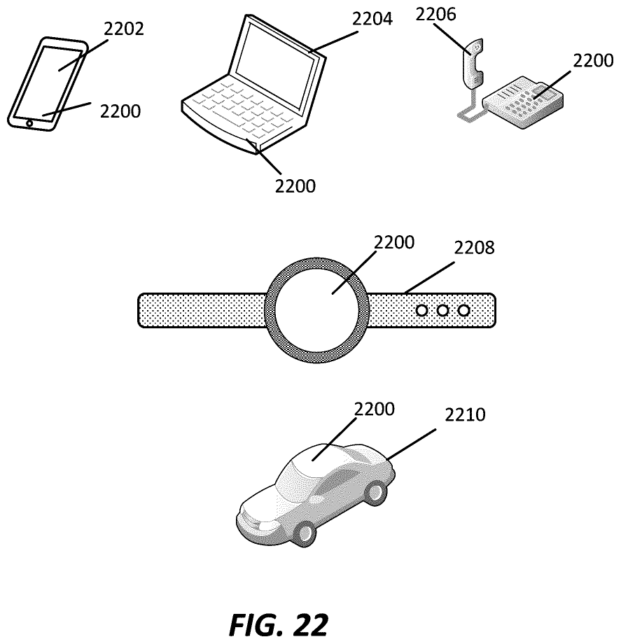

FIG. 22 illustrates various electronic devices that may be integrated with any of the aforementioned device, integrated device, integrated circuit (IC) package, integrated circuit (IC) device, semiconductor device, integrated circuit, die, chip, interposer, package, package-on-package (PoP), System in Package (SiP), or System on Chip (SoC). For example, a mobile phone device 2202, a laptop computer device 2204, a fixed location terminal device 2206, a wearable device 2208, or automotive vehicle 2210 may include a device 2200 as described herein. The device 2200 may be, for example, any of the devices and/or integrated circuit (IC) packages described herein. The devices 2202, 2204, 2206 and 2208 and the vehicle 2210 illustrated in FIG. 22 are merely exemplary. Other electronic devices may also feature the device 2200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, data centers, artificial intelligence (AI) centers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-8, 9A-9B, 10-11, 12A-12B, 13, 14A-14F, 15-16, 17A-17C, and 18-22 may be rearranged and/or combined into a single component, process, feature or function or embodied in several components, processes, or functions. Additional elements, components, processes, and/or functions may also be added without departing from the disclosure. It should also be noted FIGS. 1-8, 9A-9B, 10-11, 12A-12B, 13, 14A-14F, 15-16, 17A-17C, and 18-22 and its corresponding description in the present disclosure is not limited to dies and/or ICs. In some implementations, FIGS. 1-8, 9A-9B, 10-11, 12A-12B, 13, 14A-14F, 15-16, 17A-17C, and 18-22 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. An object that is coupled to another object may mean that the object is touching the other object. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect, as used in the disclosure, can include various metal materials, such as copper and/or aluminum. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A device comprising a memory device comprising: a first memory chip comprising: a first memory portion; and a first processor in memory portion, wherein the first processor in memory portion includes a first plurality of logic cells and at least one first capacitor; and a second memory chip coupled to the first memory chip.

Aspect 2: The device of aspect 1, wherein the memory device is a stack of memory chips.

Aspect 3: The device of aspects 1 through 2, wherein the first memory chip is coupled to the second memory chip through hybrid bonding.

Aspect 4: The device of aspect 3, wherein hybrid bonding includes copper to copper bonding.

Aspect 5: The device of aspects 1 through 4, wherein the first processor in memory portion is located along a periphery of the first memory chip.

Aspect 6: The device of aspects 1 through 5, wherein the at least one first capacitor vertically overlaps with the first plurality of logic cells.

Aspect 7: The device of aspects 1 through 6, wherein the first memory chip comprises a first die substrate; a first plurality of memory cells; a first die interconnection portion, wherein the at least one first capacitor is located in the first die interconnection portion; and a first plurality of pad interconnects.

Aspect 8: The device of aspect 7, wherein the first memory portion includes the first plurality of memory cells.

Aspect 9: The device of aspect 7, wherein the second memory chip comprises: a second memory portion; and a second processor in memory portion, wherein the second processor in memory portion includes a second plurality of logic cells and at least one second capacitor.

Aspect 10: The device of aspect 8, wherein the second memory portion vertically overlaps with the first memory portion.

Aspect 11: The device of aspect 10, wherein the second processor in memory portion vertically overlaps with the first processor in memory portion.

Aspect 12: The device of aspect 8, further comprising a third memory chip coupled to the second memory chip, wherein the third memory chip comprises: a third memory portion; and a third processor in memory portion, wherein the third processor in memory portion includes a third plurality of logic cells and at least one third capacitor.

Aspect 13: The device of aspect 12, wherein the third memory portion vertically overlaps with the first memory portion, and wherein the third processor in memory portion vertically overlaps with the first processor in memory portion.

Aspect 14: The device of aspects 1 through 13, wherein the first memory chip further includes a first plurality of back side interconnects, wherein the second memory chip further includes a plurality of pad interconnects, and wherein the first plurality of back side interconnects is coupled to the plurality of pad interconnects.

Aspect 15: The device of aspects 1 through 14, wherein a back side of the first memory chip is coupled to a front side of the second memory chip.

Aspect 16: The device of aspects 1 through 15, further comprising a substrate; and a chip coupled to the substrate, wherein the memory device is coupled to the substrate, and wherein the memory device is located adjacent to the chip.

Aspect 17: The device of aspect 10, wherein the memory device is a first chiplet based on a first technology node, and wherein the chip is a second chiplet based on a second technology node, that is different from the first technology node.

Aspect 18: The device of aspects 1 through 17, wherein the memory device is a high bandwidth memory (HBM), and wherein the chip is implemented as a System on Chip (SoC).

Aspect 19: The device of aspects 1 through 18, wherein the first memory chip is a first chiplet based on a first technology node, and wherein the second memory chip is a second chiplet based on a second technology node, that is different from the first technology node.

Aspect 20: The device of aspect 19, wherein the first technology node specifies a first minimum dimension for transistor sizes for the first chiplet, wherein the second technology node specifies a second minimum dimension for transistor sizes for the second chiplet, and wherein the second minimum dimension is different than the first minimum dimension.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a memory device comprising:
a first memory chip comprising:
a first memory portion; and
a first processor in memory portion, wherein the first processor in memory portion includes a first plurality of logic cells and at least one first capacitor; and
a second memory chip coupled to the first memory chip.

2. The device of claim 1, wherein the memory device is a stack of memory chips.

3. The device of claim 1, wherein the first memory chip is coupled to the second memory chip through hybrid bonding.

4. The device of claim 3, wherein hybrid bonding includes copper to copper bonding.

5. The device of claim 1, wherein the first processor in memory portion is located along a periphery of the first memory chip.

6. The device of claim 1, wherein the at least one first capacitor vertically overlaps with the first plurality of logic cells.

7. The device of claim 1, wherein the first memory chip comprises:
a first die substrate;
a first plurality of memory cells;
a first die interconnection portion, wherein the at least one first capacitor is located in the first die interconnection portion; and
a first plurality of pad interconnects.

8. The device of claim 7, wherein the first memory portion includes the first plurality of memory cells.

9. The device of claim 7, wherein the second memory chip comprises:
a second memory portion; and
a second processor in memory portion, wherein the second processor in memory portion includes a second plurality of logic cells and at least one second capacitor.

10. The device of claim 8, wherein the second memory portion vertically overlaps with the first memory portion.

11. The device of claim 10, wherein the second processor in memory portion vertically overlaps with the first processor in memory portion.

12. The device of claim 8, further comprising a third memory chip coupled to the second memory chip, wherein the third memory chip comprises:
a third memory portion; and
a third processor in memory portion, wherein the third processor in memory portion includes a third plurality of logic cells and at least one third capacitor.

13. The device of claim 12,
wherein the third memory portion vertically overlaps with the first memory portion, and
wherein the third processor in memory portion vertically overlaps with the first processor in memory portion.

14. The device of claim 1,
wherein the first memory chip further includes a first plurality of back side interconnects,
wherein the second memory chip further includes a plurality of pad interconnects, and
wherein the first plurality of back side interconnects is coupled to the plurality of pad interconnects.

15. The device of claim 1, wherein a back side of the first memory chip is coupled to a front side of the second memory chip.

16. The device of claim 1, further comprising:
a substrate; and
a chip coupled to the substrate,
wherein the memory device is coupled to the substrate, and
wherein the memory device is located adjacent to the chip.

17. The device of claim 10,
wherein the memory device is a first chiplet based on a first technology node, and
wherein the chip is a second chiplet based on a second technology node, that is different from the first technology node.

18. The device of claim 1,
wherein the memory device is a high bandwidth memory (HBM), and
wherein the chip is implemented as a System on Chip (SoC).

19. The device of claim 1,
wherein the first memory chip is a first chiplet based on a first technology node, and
wherein the second memory chip is a second chiplet based on a second technology node, that is different from the first technology node.

20. The device of claim 19,
wherein the first technology node specifies a first minimum dimension for transistor sizes for the first chiplet,
wherein the second technology node specifies a second minimum dimension for transistor sizes for the second chiplet, and
wherein the second minimum dimension is different than the first minimum dimension.
